(19) United States
(12) Patent Application Publication
(10) Pub. No.: US 2024/0300066 A1
(43) Pub. Date: Sep. 12, 2024

(54) POLISHING PAD AND PREPARING METHOD OF SEMICONDUCTOR DEVICE

(71) Applicant: SK enpulse Co., Ltd., Gyeonggi-do (KR)

(72) Inventors: Chang Gyu IM, Seoul (KR); Jang Won SEO, Seoul (KR); Jong Wook YUN, Seoul (KR); Joon Ho AN, Seoul (KR)

(21) Appl. No.: 18/590,378

(22) Filed: Feb. 28, 2024

(30) Foreign Application Priority Data
Mar. 6, 2023 (KR) 10-2023-0029002

(51) Int. Cl. B24B 37/20; B24B 37/04; B24B 37/22; H01L 21/306

(52) U.S. Cl. CPC B24B 37/205; B24B 37/042; B24B 37/22; H01L 21/30625

(57) ABSTRACT

The present invention provides a polishing pad, which includes a polishing layer including a first surface that is a polishing surface and a second surface that is the back surface of the first surface and including first through holes formed to penetrate from the first surface to the second surface; windows placed within the first through holes; and a support layer placed on the side of the second surface of the polishing layer, including a third surface that is placed on the side of the polishing layer and a fourth surface that is the back surface of the third surface, and including second through holes formed to penetrate from the third surface to the fourth surface and connected to the first through holes. The windows include a first region where the height of a top surface is lower than the height of the first surface.

### CROSS-REFERENCE TO RELATED APPLICATION

The This application claims priority under 35 U.S.C. § 119 to Korean Patent Application No. 10-2023-0029002 filed on Mar. 6, 2023, which is incorporated herein by reference in its entirety.

### TECHNICAL FIELD

The present invention relates to a polishing pad used in a process of chemically/mechanically planarizing a semiconductor substrate in a process of fabricating a semiconductor device, and a method of fabricating a semiconductor device using the polishing pad.

### BACKGROUND ART

The chemical mechanical planarization (CMP) or chemical mechanical polishing (CMP) process is used in various fields and for various purposes. The CMP process is performed on a predetermined polishing surface of a polishing object, and can be performed for the purposes of flattening a polishing surface, removing aggregated materials, preventing crystal lattice damage, and removing scratches and contaminants.

CMP process technology for semiconductor processes can be classified according to the film quality of a polishing object or a surface shape after polishing. For example, depending on the film quality of a polishing object, it can be classified into single silicon or poly silicon, and it can be classified into various oxide films or metal film CMP processes such as tungsten (W), copper (Cu), aluminum (Al), ruthenium (Ru), and tantalum (Ta), depending on the type of impurity. In addition, depending on a surface shape after polishing, it can be classified into a process for alleviating the roughness of a substrate surface, a process for flattening steps caused by multi-layer circuit wiring, and an element separation process for selectively forming circuit wiring after polishing.

The CMP process can be applied as multiple processes in the process of fabricating a semiconductor device. A semiconductor device includes multiple layers, and each layer includes complex and fine circuit patterns. In addition, recently, semiconductor devices are evolving in a direction where individual chip sizes are decreasing and the patterns of each layer are becoming complex and fine. Accordingly, in a process of fabricating a semiconductor device, the purpose of the CMP process has expanded not only to flatten circuit wiring, but also to separate circuit wiring and improve the wiring surface. As a result, more sophisticated and reliable CMP performance is required.

A polishing pad used in this CMP process is a process component that processes a polishing surface to a required level through friction. The polishing pad can be considered as an important factor in the thickness uniformity of a polishing object after polishing, the flatness of a polishing surface, and polishing quality.

### DISCLOSURE

### Technical Problem

Therefore, the present invention has been made in view of the above problems, and it is one object of the present invention to provide a polishing pad having windows for a polishing endpoint detection function and preventing the windows from negatively affecting polishing performance as a local heterogeneous part of an entire polishing layer, wherein the entire light transmission region of the windows is not worn at all during a polishing process, or even when the region is worn, the combination of the degree of wear and the ratio of the area of the worn region to the entire light transmission region is advantageous in maintaining the polishing endpoint detection function for a long time.

It is another object of the present invention to provide a method of fabricating a high-quality semiconductor device without discarding and replacing the polishing pad as the polishing endpoint detection function is maintained excellently for a long time by applying the polishing pad, which has the above-described technical advantages, as a process component.

### Technical Solution

In accordance with one aspect of the present invention, provided is a polishing pad including a polishing layer including a first surface that is a polishing surface and a second surface that is a back surface of the first surface and including first through holes formed to penetrate from the first surface to the second surface; windows placed within the first through holes; and a support layer placed on a side of the second surface of the polishing layer, including a third surface that is placed on a side of the polishing layer and a fourth surface that is a back surface of the third surface, and including second through holes formed to penetrate from the third surface to the fourth surface and connected to the first through holes, wherein the windows include a first region where a height of a top surface is lower than a height of the first surface, and the polishing pad has a value of approximately 0.00 to approximately 1.45 as calculated by Equation 1 below:

$$\frac{P}{T} \times ( Fa - Ia ) \qquad [ Equation 1 ]$$

### [Condition 1]

In a state in which the first surface and a polishing target surface of a silicon wafer are arranged to face each other, polishing is performed under Condition 1 that a rotation speed of the silicon wafer is 87 rpm, a rotation speed of the polishing pad is 93 rpm, a pressing load of the polishing target surface of the silicon wafer against the first surface is 3.5 psi, a flow rate of distilled water injected onto the first surface is 200 mL/min, a rotation speed of a conditioner that processes the first surface is 101 rpm, and a vibration movement speed of the conditioner is 19 times/min.

In Equation 1, T is an area value of a light transmission region of the window top surface, P is an area (mm²) value of a worn region of the light transmission region after polishing for 20 hours under Condition 1, Ia is a surface roughness (Sa, μm) value of the first region before polishing, and Fa is a surface roughness (Sa, μm) value of the first region after polishing for 20 hours under Condition 1.

In one embodiment the polishing pad may include two or more first through holes, two or more second through holes, and two or more windows.

In one embodiment, a height difference between the first surface and the first region may be approximately 100 μm to approximately 1.5 mm.

In one embodiment, the windows may further include a second region where a height of a top surface is equal to a height of the first surface, the first region may be located in a center of the window, and the second region may be located on the outer periphery of the window.

In one embodiment, the windows may have a light transmittance of approximately 10% or more for light with a wavelength of 450 nm after polishing for 20 hours for a thickness of 2 mm under Condition 1.

In one embodiment, after polishing for a time under Condition 1, when the windows have a light transmittance of 2.5% or less for light with a wavelength of 450 nm, the α may be approximately 50 or more.

In one embodiment, an Sa change rate of the first region calculated using Equation 2 below may be 0% to 160%:

$$\frac{( Fa - Ia )}{Ia} \times 100 \qquad [ Equation 2 ]$$

In Equation 2, la is a surface roughness (Sa, μm) value of the first region before polishing, and Fa is a surface roughness (Sa, μm) value of the first region after polishing for 20 hours under Condition 1.

In one embodiment, an Spk change rate of the first region calculated using Equation 3 below may be 0% to 130%:

$$\frac{( Fp - Ip )}{Ip} \times 100 \qquad [ Equation 3 ]$$

In Equation 3, Ip is a surface roughness (Spk, μm) value of the first region before polishing, and Fp is a surface roughness (Spk, μm) value of the first region after polishing for 20 hours under Condition 1.

In one embodiment, a surface roughness (Svk) change rate of the first region calculated using Equation 4 below may be 0% to approximately 320%:

$$\frac{( Fv - Iv )}{Iv} \times 100 \qquad [ Equation 4 ]$$

In Equation 4, Iv is a surface roughness (Svk, μm) value of the first region before polishing, and Fv is a surface roughness (Svk, μm) value of the first region after polishing for 20 hours under Condition 1.

In accordance with another aspect of the present invention, provided is a method of fabricating a semiconductor device, the method including a step of providing a polishing pad having a polishing layer including a first surface that is a polishing surface and a second surface that is a back surface of the first surface, first through holes formed to penetrate from the first surface to the second surface, and windows placed within the first through holes; and a step of positioning a polishing object so that a polishing target surface of the polishing object is in contact with the first surface and then polishing the polishing object by rotating the polishing pad and the polishing object relative to each other under pressure conditions, wherein the polishing object includes a semiconductor substrate, the polishing pad further includes a support layer placed on a side of the second surface of the polishing layer, and the support layer includes a third surface that is placed on a side of the polishing layer and a fourth surface that is a back surface of the third surface, and includes second through holes formed to penetrate from the third surface to the fourth surface and connected to the first through holes, wherein the windows include a first region where a height of a top surface is lower than a height of the first surface, and the polishing pad has a value of 0.00 to 1.45 as calculated by Equation 1:

$$\frac{P}{T} \times ( Fa - Ia ) \qquad [ Equation 1 ]$$

### [Condition 1]

In a state in which the first surface and a polishing target surface of the polishing object are arranged to face each other, polishing is performed under Condition 1 that a rotation speed of the polishing object is 87 rpm, a rotation speed of the polishing pad is 93 rpm, a pressing load of the polishing target surface of the polishing object against the first surface is 3.5 psi, a flow rate of distilled water injected onto the first surface is 200 mL/min, a rotation speed of a conditioner that processes the first surface is 101 rpm, and a vibration movement speed of the conditioner is 19 times/min.

In Equation 1, T is an area (mm²) value of a light transmission region of the window top surface, P is an area (mm²) value of a worn region of the light transmission region after polishing for 20 hours under Condition 1, Ia is a surface roughness (Sa, μm) value of the first region before polishing, and Fa is a surface roughness (Sa, μm) value of the first region after polishing for 20 hours under Condition 1.

The method of fabricating a semiconductor device may further include a step of supplying polishing slurry to the first surface. The polishing slurry may be sprayed onto the first surface through a supply nozzle, and a flow rate of the polishing slurry sprayed through the supply nozzle may be approximately 10 ml/min to approximately 1,000 ml/min.

A rotation speed of each of the polishing object and the polishing pad may be approximately 10 rpm to approximately 500 rpm.

In one embodiment, the method of fabricating a semiconductor device may further include a step of roughening the first surface using a conditioner. A rotation speed of the conditioner may be approximately 50 rpm to approximately 150 rpm, and a pressing load of the conditioner against the first surface may be approximately 1 lb to approximately 10 lb.

In one embodiment, a load with which the polishing target surface of the polishing object is pressed against the first surface may be approximately 0.01 psi to approximately 20 psi.

In the method of fabricating a semiconductor device according to one embodiment, a height difference between the first surface and the first region may be 100 μm to 1.5 mm.

In the method of fabricating a semiconductor device according to one embodiment, the windows may further include a second region where a height of a top surface is equal to a height of the first surface, the first region may be located in a center of the window, and the second region may be located on the outer periphery of the window.

In the method of fabricating a semiconductor device according to one embodiment, the windows may have a light transmittance of 10% or more for light with a wavelength of 450 nm after polishing for 20 hours for a thickness of 2 mm under Condition 1.

In the method of fabricating a semiconductor device according to one embodiment, after polishing for a time under Condition 1, when the windows have a light transmittance of 2.5% or less for light with a wavelength of 450 nm, the α may be 50 or more.

In accordance with yet another aspect of the present invention, provided is a polishing pad including a polishing layer including a first surface that is a polishing surface and a second surface that is a back surface of the first surface and including first through holes formed to penetrate from the first surface to the second surface; windows placed within the first through holes; and a support layer placed on a side of the second surface of the polishing layer, including a third surface that is placed on a side of the polishing layer and a fourth surface that is a back surface of the third surface, and including second through holes formed to penetrate from the third surface to the fourth surface and connected to the first through holes, wherein the windows include a first region where a height of a top surface is lower than a height of the first surface, and an Sa change rate of the first region calculated using Equation 2 below is 0% to 160%.

$$\frac{( Fa - Ia )}{Ia} \times 100 \qquad [ Equation 2 ]$$

### [Condition 1]

In a state in which the first surface and a polishing target surface of a silicon wafer are arranged to face each other, polishing is performed under Condition 1 that a rotation speed of the silicon wafer is 87 rpm, a rotation speed of the polishing pad is 93 rpm, a pressing load of the polishing target surface of the silicon wafer against the first surface is 3.5 psi, a flow rate of distilled water injected onto the first surface is 200 mL/min, a rotation speed of a conditioner that processes the first surface is 101 rpm, and a vibration movement speed of the conditioner is 19 times/min.

In Equation 2, la is a surface roughness (Sa, μm) value of the first region before polishing, and Fa is a surface roughness (Sa, μm) value of the first region after polishing for 20 hours under Condition 1.

### Advantageous Effects

The present invention can provide a polishing pad having windows for a polishing endpoint detection function and preventing the windows from negatively affecting polishing performance as a local heterogeneous part of an entire polishing layer, wherein the entire light transmission region of the windows is not worn at all during a polishing process, or even when the region is worn, the combination of the degree of wear and the ratio of the area of the worn region to the entire light transmission region is advantageous in maintaining the polishing endpoint detection function for a long time.

The present invention can provide a method of fabricating a high-quality semiconductor device without discarding and replacing the polishing pad as the polishing endpoint detection function is maintained excellently for a long time by applying the polishing pad, which has the above-described technical advantages, as a process component.

### DESCRIPTION OF DRAWINGS

FIG. 1 schematically shows a cross-section in the thickness direction of the window-containing region of the polishing pad according to one embodiment.

FIG. 2 schematically shows a cross-section in the thickness direction of the window-containing region of the polishing pad according to another embodiment.

FIG. 3 schematically shows a floor plan of the polishing pad according to one embodiment.

FIG. 4 schematically shows a cross-section in the thickness direction of the window-containing region of a polishing pad according to another embodiment.

FIG. 5 is an enlarged schematic diagram of part A of FIG. 1.

FIG. 6 is a schematic diagram schematically showing the device configuration of the method of fabricating a semiconductor device according to one embodiment.

### BEST MODE

The present invention will now be described more fully with reference to the accompanying drawings, in which exemplary embodiments of the invention are shown. The invention may, however, be embodied in many different forms and should not be construed as being limited to the embodiments set forth herein; rather, these embodiments are provided so that this disclosure will be thorough and complete, and will fully convey the concept of the invention to those skilled in the art. The present invention is defined only by the categories of the claims.

In the drawings, the thickness of some components is shown enlarged, when necessary, to clearly express the layer or region. In addition, in the drawings, for convenience of explanation, the thickness of some layers and regions are exaggerated. Like reference numerals refer to like elements throughout the specification.

In addition, when an element such as a layer, a film, a region, and a constituent is referred to as being “on” another element, the element can be directly on another element or an intervening element can be present. When a part is said to be “right on top” of another part, it is interpreted to mean that there are no other parts therebetween. In addition, when a part of a layer, membrane, region, or plate is said to be “under”, “beneath” or “underneath” another part, this means not only when it is “immediately below” another part, but also when there is another part therebetween. When a part is said to be “right below” another part, it is interpreted to mean that there are no other parts therebetween.

Hereinafter, an embodiment according to the present invention will be described in detail.

One embodiment of the present invention provides a polishing pad including a polishing layer including a first surface that is a polishing surface and a second surface that is the back surface of the first surface and including first through holes formed to penetrate from the first surface to the second surface; windows placed within the first through holes; and a support layer placed on the side of the second surface of the polishing layer, including a third surface that is placed on the side of the polishing layer and a fourth surface that is the back surface of the third surface, and including second through holes formed to penetrate from the third surface to the fourth surface and connected to the first through holes. The windows include a first region whose top surface height is lower than the height of the first surface, and the polishing pad has a value of 0.00 to 1.45 as calculated by Equation 1 below.

$$\frac{P}{T} \times ( Fa - Ia ) \qquad [ Equation 1 ]$$

### [Condition 1]

In a state in which the first surface and a polishing target surface of a silicon wafer are arranged to face each other, polishing is performed under Condition 1 that a rotation speed of the silicon wafer is 87 rpm, a rotation speed of the polishing pad is 93 rpm, a pressing load of the polishing target surface of the silicon wafer against the first surface is 3.5 psi, a flow rate of distilled water injected onto the first surface is 200 mL/min, a rotation speed of a conditioner that processes the first surface is 101 rpm, and a vibration movement speed of the conditioner is 19 times/min.

In Equation 1, T is an area (mm²) value of a light transmission region of the window top surface, P is an area (mm²) value of a worn region of the light transmission region after polishing for 20 hours under Condition 1, Ia is a surface roughness (Sa, μm) value of the first region before polishing, and Fa is a surface roughness (Sa, μm) value of the first region after polishing for 20 hours under Condition 1.

In Equation 1, T and P are each numerical values of the unit mm² and consist only of unitless numbers. Ia and Fa are each numerical values of the unit μm and consist only of unitless numbers.

Condition 1 is a measurement condition for deriving P and Fa, and does not limit the process conditions of a polishing process to which the polishing pad is applied.

The polishing pad is one of essential raw materials for a polishing process that flattens a surface, and is especially one of important process components in a process for fabricating semiconductor devices. The purpose of the polishing pad is to improve the convenience of subsequent processing by flattening uneven structures and removing surface defects. The polishing process is a process that is applied to other technology fields in addition to the semiconductor technology field, but compared to other technology fields, the precision of the polishing process required in the semiconductor fabricating process may be said to be at the highest level. Considering the recent trend toward high integration and ultra-miniaturization of semiconductor devices, the quality of semiconductor devices may be greatly reduced even by very small errors in the polishing process during the manufacturing process of semiconductor devices. Accordingly, for fine control of the polishing process, polishing endpoint detection technology was introduced to stop polishing when a semiconductor substrate has been accurately polished to a desired degree. The polishing endpoint detection technology is a technology that detects an exact polishing endpoint by optically detecting the thickness of a semiconductor substrate using light passing through a window capable of transmitting light and provided in a polishing pad. The window is a component that provides a locally heterogeneous surface of the entire polishing surface of the polishing pad. As the polishing process progresses, the window and the polishing layer wear out at different rates, or the surfaces wear out to have different textures. Thus, the heterogeneity of the boundary between the polishing surface and the window surface may cause defects in the polishing target surface of the semiconductor substrate. In addition, depending on the wear pattern of the window, the light transmission function is rapidly reduced and the polishing endpoint detection function is lost, which may shorten the lifespan of the polishing pad. The polishing pad according to one embodiment may prevent the window from negatively affecting polishing performance as a heterogeneous part by satisfying the value of Equation 1 within a predetermined range. In addition, the polishing pad may achieve the effect of maintaining the polishing endpoint detection function of the window excellently for a long time.

In one embodiment, the value of Equation 1 may be approximately 0.00 to approximately 1.45, for example, approximately 0.00 to approximately 1.40, for example, approximately 0.00 to approximately 1.35, for example, approximately 0.00 to approximately 1.30, for example, approximately 0.00 to approximately 1.25, for example, approximately 0.00 to approximately 1.20, for example, approximately 0.00 to approximately 1.15, for example, approximately 0.00 to approximately 1.10, for example, approximately 0.00 to approximately 1.05, for example, approximately 0.00 to approximately 1.00, for example, approximately 0.00 to approximately 0.95, for example, approximately 0.00 to approximately 0.90, for example, approximately 0.00 to approximately 0.85, for example, approximately 0.00 to approximately 0.80, for example, approximately 0.00 or more and less than approximately 0.80. When the value of Equation 1 satisfies the above range, the windows show that an entire light transmission region is not worn at all during a polishing process, or even when the region is worn, the combination of the degree of wear and the area of the worn region in the entire light transmission region may show an appropriate effect for maintaining the polishing endpoint detection function for a long time.

In one embodiment, a surface roughness (Sa) change rate of the first region calculated using Equation 2 below may be approximately 0% to approximately 160%, for example, approximately 0% to approximately 150%, for example, approximately 0% to approximately 140%, for example, approximately 0% to approximately 130%, for example, approximately 0% to approximately 120%, for example, approximately 0% to approximately 110%, for example, approximately 0% to approximately 100%, for example, approximately 0% to approximately 90%, for example, approximately 0% to approximately 85%.

$$\frac{( Fa - Ia )}{Ia} \times 100 \qquad [ Equation 2 ]$$

In Equation 2, la is a surface roughness (Sa, μm) value of the first region before polishing, and Fa is a surface roughness (Sa, μm) value of the first region after polishing for 20 hours under Condition 1.

In one embodiment, a surface roughness (Spk) change rate of the first region calculated using Equation 3 below may be approximately 0% to approximately 130%, for example, approximately 0% to approximately 110%, for example, approximately 0% to approximately 90%, for example, approximately 0% to approximately 70%, for example, approximately 0% to approximately 65%.

$$\frac{( Fp - Ip )}{Ip} \times 100 \qquad [ Equation 3 ]$$

In Equation 3, Ip is a surface roughness (Spk, μm) value of the first region before polishing, and Fp is a surface roughness (Spk, μm) value of the first region after polishing for 20 hours under Condition 1.

In one embodiment, a surface roughness (Svk) change rate of the first region calculated using Equation 4 below may be approximately 0% to approximately 320%, for example, approximately 0% to approximately 300%, for example, approximately 0% to approximately 280%, for example, approximately 0% to approximately 260%, for example, approximately 0% to approximately 240%, for example, approximately 0% to approximately 220%.

$$\frac{( Fv - Iv )}{Iv} \times 100 \qquad [ Equation 4 ]$$

In Equation 4, Iv is a surface roughness (Svk, μm) value of the first region before polishing, and Fv is a surface roughness (Svk, μm) value of the first region after polishing for 20 hours under Condition 1.

When the values of Equation 2, Equation 3, and Equation 4 each or more than two values simultaneously satisfy the above-mentioned range, there may be virtually no wear and tear on the window 102. Even when wear occurs, the degree of wear may be more advantageous to achieve an effect that has little practical influence on the deterioration of the polishing endpoint detection function by controlling the area ratio of a worn region in the light transmission region of the window 102.

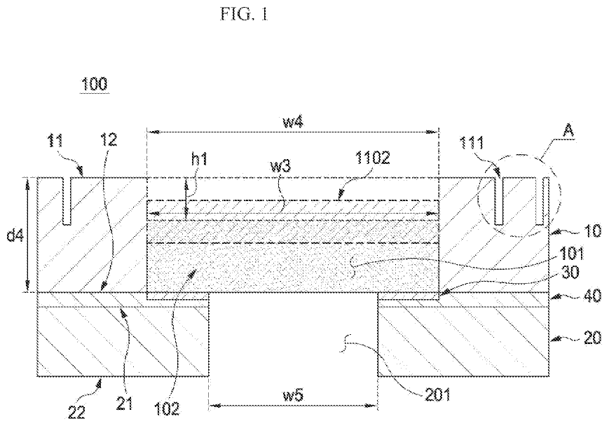

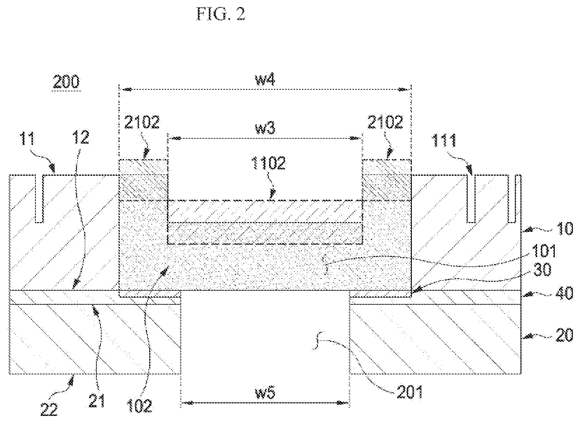

FIG. 1 schematically shows a cross-section in the thickness direction of the window-containing region of a polishing pad 100 according to one embodiment, and FIG. 2 schematically shows a cross-section in the thickness direction of the window-containing region of a polishing pad 200 according to one embodiment. Referring to FIG. 1, the polishing pad 100 includes a polishing layer 10 including a first surface 11 that is a polishing surface and a second surface 12 that is the back surface of the first surface 11 and including first through hole 101 formed to penetrate from the first surface 11 to the second surface 12. In addition, the polishing pad 100 includes a support layer 20 including a third surface 21 located on the side of the polishing layer 10 and a fourth surface 22 that is the back surface of the third surface 21 and including second through hole 201 formed to penetrate from the third surface 21 to the fourth surface 22 and connected to the first through hole 101. The second through hole 201 is formed to be connected to the first through hole 101, so that the polishing pad 100 includes an optical path penetrating the entire thickness from the top to the bottom, and an optical end point detection method through the window 102 may be applied effectively.

The window 102 includes a first region 1102 where the height of a top surface is lower than the height of the first surface 11. By including the first region 1102 in the window 102, light transmittance for the polishing endpoint detection function may be maintained at a predetermined level for a long time. In one embodiment, the height difference (h1) between the first surface 11 and the first region 1102 may be approximately 100 μm to approximately 1.5 mm, for example, approximately 100 μm to approximately 1.4 mm, for example, approximately 100 μm to 1.3 mm, for example, approximately 100 μm to approximately 1.2 mm, for example, approximately 100 μm to 1.1 mm, for example, approximately 100 μm to approximately 1.0 mm, for example, approximately 200 μm to approximately 1.5 mm, for example, approximately 250 μm to approximately 1.5 mm, for example, approximately 300 μm to approximately 1.5 mm, for example, approximately 350 μm to approximately 1.5 mm, for example, approximately 400 μm to approximately 1.5 mm, for example, approximately 450 μm to approximately 1.5 mm, for example, approximately 480 μm to approximately 1.5 mm, for example, approximately 200 μm to approximately 1.2 mm, for example, approximately 300 μm to approximately 1.2 mm, for example, approximately 400 μm to approximately 1.0 mm, for example, approximately 480 μm to approximately 1.0 mm, for example, approximately 500 μm to approximately 900 μm. When the height difference (h1) between the first region 1102 and the first surface 11 is within the above range, the light transmittance of window 102 may be maintained above a certain level for a long time. In addition, the window 102 may be prevented from having a negative impact on polishing performance as localized heterogeneous areas on the first surface 11.

Referring to FIG. 2, in a polishing pad 200, the window 102 may further include a second region 2102 where the height of a top surface is equal to the height of the first surface 11. In addition, the first region 1102 may be located in the center of the window 102, and the second region 2102 may be located in the outer periphery of the window 102.

The fact that the height of the top surface of the window 102 is the same as the height of the first surface 11 means that the height is substantially the same, and should be understood to encompass the fact that even if there is a certain height difference within the error range, it is considered to be substantially the same height. Specifically, when the height difference between the top surface of window 102 and the first surface 11 is 0 μm to 30 μm, the two heights should be understood as being substantially the same.

The center of the window 102 refers to a predetermined region including the center of gravity of a window 10, and the outer periphery of the window 102 refers to a predetermined region surrounding the center outer periphery of the window 10.

When the window 102 includes both the first region 1102 and the second region 2102, wear of the light transmission region of the window 102 may not substantially occur. As a result, the maintenance time of the polishing endpoint detection function may be maximized by maintaining the light transmittance of the window 102 above a predetermined level for a long period of time. When the second region 2101 is located in the outer periphery of the window 102, and the first region 1102 is located in the center of the window 102, the effect of maintaining the light transmittance of the window 102 for a long time may be further maximized, and mutual heterogeneity may be minimized at the boundary between the window 102 and the polishing layer 10.

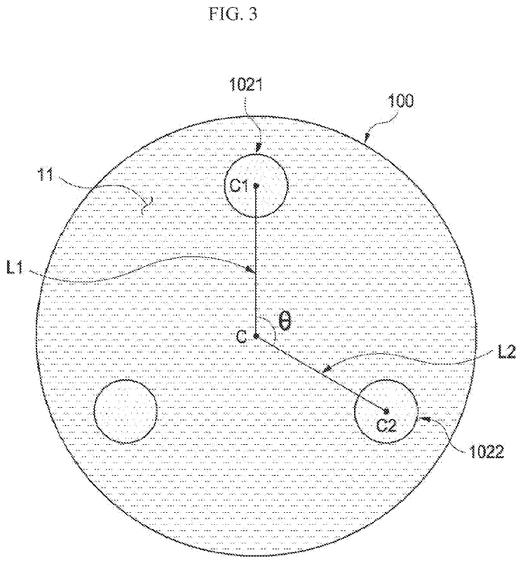

FIG. 3 schematically shows a floor plan of the polishing pad 100 according to one embodiment. Referring to FIG. 3, the windows 102 may have a circular or oval shape. The polishing pad 100 may include two or more first through holes 101, two or more second through holes 201, and two or more windows 102.

In one embodiment, when the polishing pad 100 includes two or more windows 102, any one of the windows 102 is referred to as a first window 1021, and the other window 102 adjacent to the first window 1021 is referred to as a second window 1022, the angle (0) between a straight line (L1) connecting the center (C1) of the first window 1021 and the center (C) of the polishing pad 100 and a straight line (L2) connecting the center (C2) of the second window 1022 and the center (C) of the polishing pad 100 may be approximately 90° to approximately 150°, for example, approximately 95° to approximately 150°, for example, approximately 100° to approximately 150°, for example, approximately 105° to approximately 150°, for example, approximately 110° to approximately 150°, for example, approximately 90° to approximately 145°, for example, approximately 90° to approximately 140°, for example, approximately 90° to approximately 135°, for example, approximately 90° to approximately 130°, for example, approximately 90° to approximately 125°, for example, approximately 95° to approximately 140°, for example, approximately 100° to approximately 135°, for example, approximately 105° to approximately 130°, for example, approximately 110° to approximately 125°. When the polishing pad 100 has a plurality of windows 102 and such arrangement, during the polishing process while rotating the polishing pad 100, more reliable results may be produced in the polishing endpoint detection step. In addition, by ensuring the appropriate placement spacing of the windows, even though the surface of the windows 102 of the first surface 11 forms multiple heterogeneous regions, scratches caused by the boundary between the windows 102 and the polishing layer 10 may be effectively prevented.

When the windows 102 have a circular shape, the diameter of the window 102 may be approximately 15 mm to approximately 35 mm, for example, approximately 15 mm to approximately 34 mm, for example, approximately 15 mm to approximately 33 mm, for example, approximately 15 mm to approximately 32 mm, for example, approximately 15 mm to approximately 31 mm, for example, approximately 15 mm to approximately 30 mm, for example, approximately 15 mm to approximately 29 mm, for example, approximately 15 mm to approximately 28 mm, for example, approximately 15 mm to approximately 27 mm, for example, approximately 15 mm to approximately 26 mm, for example, approximately 15 mm to approximately 25 mm, for example, approximately 15 mm to approximately 24 mm, for example, approximately 15 mm to approximately 23 mm, for example, approximately 15 mm to approximately 22 mm, for example, approximately 15 mm to approximately 21 mm, for example, approximately 15 mm to approximately 20.5 mm, for example, approximately 16 mm to approximately 35 mm, for example, approximately 17 mm to approximately 35 mm, for example, approximately 18 mm to approximately 35 mm, for example, approximately 19 mm to approximately 35 mm, for example, approximately 17 mm to approximately 30 mm, for example, approximately 18 mm to approximately 28 mm, for example, approximately 19 mm to approximately 25 mm, for example, approximately 19 mm to approximately 24 mm, for example, approximately 19 mm to approximately 22 mm, for example, approximately 19 mm to approximately 21 mm, for example, approximately 19 mm to approximately 20.5 mm.

When the windows 102 have an oval shape, the longest diameter of the window 102 may be approximately 15 mm to approximately 35 mm, for example, approximately 15 mm to approximately 34 mm, for example, approximately 15 mm to approximately 33 mm, for example, approximately 15 mm to approximately 32 mm, for example, approximately 15 mm to approximately 31 mm, for example, approximately 15 mm to approximately 30 mm, for example, approximately 15 mm to approximately 29 mm, for example, approximately 15 mm to approximately 28 mm, for example, approximately 15 mm to approximately 27 mm, for example, approximately 15 mm to approximately 26 mm, for example, approximately 15 mm to approximately 25 mm, for example, approximately 15 mm to approximately 24 mm, for example, approximately 15 mm to approximately 23 mm, for example, approximately 15 mm to approximately 22 mm, for example, approximately 15 mm to approximately 21 mm, for example, approximately 15 mm to approximately 20.5 mm, for example, approximately 16 mm to approximately 35 mm, for example, approximately 17 mm to approximately 35 mm, for example, approximately 18 mm to approximately 35 mm, for example, approximately 19 mm to approximately 35 mm, for example, approximately 17 mm to approximately 30 mm, for example, approximately 18 mm to approximately 28 mm, for example, approximately 19 mm to approximately 25 mm, for example, approximately 19 mm to approximately 24 mm, for example, approximately 19 mm to approximately 22 mm, for example, approximately 19 mm to approximately 21 mm, for example, approximately 19 mm to approximately 20.5 mm.

When the size of the window 102 satisfies this range, a sufficient light transmission region may be secured for polishing endpoint detection. In addition, since the area of the surface of the window 102 on the first surface 11 is appropriate as a localized heterogeneous area, it can be advantageous to minimize the deterioration of polishing performance, such as scratches caused by the boundary area between the polishing layer 10 and the window 102.

The window 102 is placed within the first through hole 101. In one embodiment, the second through hole 201 may be smaller than the first through hole 101. By forming the second through hole 201 smaller than the first through hole 101, the bottom cross-section of the window 102 creates a support surface that may support the window 102 on the third surface 21. The window 102 may be firmly mounted through the support surface, and the inflow of liquid components from the first surface 11 may be effectively prevented during the polishing process.

In one embodiment, when the windows 102 are circular or oval, the shapes of the first through hole 101 and the second through hole 201 may also be circular or oval. That is, the first through hole 101 and the second through hole 201 may have a shape that conforms to the shape of the windows 102. When the windows 102 and the first through hole 101 and the second through hole 201 have shapes that conform to each other, the light transmission region of the windows 102 may be secured.

In one embodiment, the window 102 may be circular, the first through hole 101 may be circular, and the second through hole 201 may be circular. Here, the diameter of the window 102 may be the same as the diameter (w4) of the first through hole 101, or may be smaller than the diameter (w4) of the first through hole 101. For example, the difference between the diameter of the window 102 and the diameter (w4) of the first through hole 101 may be approximately 0 mm to approximately 0.8 mm, for example, approximately 0 mm to approximately 0.7 mm, for example, approximately 0 mm to approximately 0.6 mm, for example, approximately 0 mm to approximately 0.5 mm. When the difference between the diameter of the window 102 and the diameter of the first through hole 101 (w4) satisfies the range, leakage of liquid components such as polishing slurry through the interface between the window 102 and the polishing layer 10 may be prevented, and the efficiency of the process of placing the window 102 within the first through hole 101 may be improved.

In one embodiment, when the first through hole 101 is circular, the diameter (w4) of the first through hole 101 may be approximately 15.5 mm to approximately 35.5 mm, for example, approximately 15.5 mm to approximately 34.5 mm, for example, approximately 15.5 mm to approximately 33.5 mm, for example, approximately 15.5 mm to approximately 32.5 mm, for example, approximately 15.5 mm to approximately 31.5 mm, for example, approximately 15.5 mm to approximately 30.5 mm, for example, approximately 15.5 mm to approximately 29.5 mm, for example, approximately 15.5 mm to approximately 28.5 mm, for example, approximately 15.5 mm to approximately 27.5 mm, for example, approximately 15.5 mm to approximately 26.5 mm, for example, approximately 15.5 mm to approximately 25.5 mm, for example, approximately 15.5 mm to approximately 24.5 mm, for example, approximately 15.5 mm to approximately 23.5 mm, for example, approximately 15.5 mm to approximately 22.5 mm, for example, approximately 15.5 mm to approximately 21.5 mm, for example, approximately 15.5 mm to approximately 21 mm, for example, approximately 16.5 mm to approximately 35.5 mm, for example, approximately 17.5 mm to approximately 35.5 mm, for example, approximately 18.5 mm to approximately 35.5 mm, for example, approximately 19.5 mm to approximately 35.5 mm, for example, approximately 17.5 mm to approximately 30.5 mm, for example, approximately 18.5 mm to approximately 28.5 mm, for example, approximately 19.5 mm to approximately 25.5 mm, for example, approximately 19.5 mm to approximately 24.5 mm, for example, approximately 19.5 mm to approximately 22.5 mm, for example, approximately 19.5 mm to approximately 21.5 mm, for example, approximately 19.5 mm to approximately 21 mm.

In one embodiment, when the first through hole 101 is oval, the longest diameter of the first through hole 101 may be approximately 15.5 mm to approximately 35.5 mm, for example, approximately 15.5 mm to approximately 34.5 mm, for example, approximately 15.5 mm to approximately 33.5 mm, for example, approximately 15.5 mm to approximately 32.5 mm, for example, approximately 15.5 mm to approximately 31.5 mm, for example, approximately 15.5 mm to approximately 30.5 mm, for example, approximately 15.5 mm to approximately 29.5 mm, for example, approximately 15.5 mm to approximately 28.5 mm, for example, approximately 15.5 mm to approximately 27.5 mm, for example, approximately 15.5 mm to approximately 26.5 mm, for example, approximately 15.5 mm to approximately 25.5 mm, for example, approximately 15.5 mm to approximately 24.5 mm, for example, approximately 15.5 mm to approximately 23.5 mm, for example, approximately 15.5 mm to approximately 22.5 mm, for example, approximately 15.5 mm to approximately 21.5 mm, for example, approximately 15.5 mm to approximately 21 mm, for example, approximately 16.5 mm to approximately 35.5 mm, for example, approximately 17.5 mm to approximately 35.5 mm, for example, approximately 18.5 mm to approximately 35.5 mm, for example, approximately 19.5 mm to approximately 35.5 mm, for example, approximately 17.5 mm to approximately 30.5 mm, for example, approximately 18.5 mm to approximately 28.5 mm, for example, approximately 19.5 mm to approximately 25.5 mm, for example, approximately 19.5 mm to approximately 24.5 mm, for example, approximately 19.5 mm to approximately 22.5 mm, for example, approximately 19.5 mm to approximately 21.5 mm, for example, approximately 19.5 mm to approximately 21 mm.

In one embodiment, when the second through hole 201 is circular, the diameter (w5) of the second through hole 201 may be approximately 7.5 mm to approximately 27.5 mm, for example, approximately 7.5 mm to approximately 26.5 mm, for example, approximately 7.5 mm to approximately 25.5 mm, for example, approximately 7.5 mm to approximately 24.5 mm, for example, approximately 7.5 mm to approximately 23.5 mm, for example, approximately 7.5 mm to approximately 22.5 mm, for example, approximately 7.5 mm to approximately 21.5 mm, for example, approximately 7.5 mm to approximately 20.5 mm, for example, approximately 7.5 mm to approximately 19.5 mm, for example, approximately 7.5 mm to approximately 18.5 mm, for example, approximately 7.5 mm to approximately 17.5 mm, for example, approximately 7.5 mm to approximately 16.5 mm, for example, approximately 7.5 mm to approximately 15.5 mm, for example, approximately 7.5 mm to approximately 14.5 mm, for example, approximately 7.5 mm to approximately 13.5 mm, for example, approximately 7.5 mm to approximately 13 mm, for example, approximately 8.5 mm to approximately 27.5 mm, for example, approximately 9.5 mm to approximately 27.5 mm, for example, approximately 10.5 mm to approximately 27.5 mm, for example, approximately 11.5 mm to approximately 27.5 mm, for example, approximately 9.5 mm to approximately 22.5 mm, for example, approximately 10.5 mm to approximately 20.5 mm, for example, approximately 11.5 mm to approximately 17.5 mm, for example, approximately 11.5 mm to approximately 16.5 mm, for example, approximately 11.5 mm to approximately 14.5 mm, for example, approximately 11.5 mm to approximately 13.5 mm, for example, approximately 11.5 mm to approximately 13 mm.

In one embodiment, when the second through hole 201 is oval, the longest diameter of the second through hole 201 may be approximately 7.5 mm to approximately 27.5 mm, for example, approximately 7.5 mm to approximately 26.5 mm, for example, approximately 7.5 mm to approximately 25.5 mm, for example, approximately 7.5 mm to approximately 24.5 mm, for example, approximately 7.5 mm to approximately 23.5 mm, for example, approximately 7.5 mm to approximately 22.5 mm, for example, approximately 7.5 mm to approximately 21.5 mm, for example, approximately 7.5 mm to approximately 20.5 mm, for example, approximately 7.5 mm to approximately 19.5 mm, for example, approximately 7.5 mm to approximately 18.5 mm, for example, approximately 7.5 mm to approximately 17.5 mm, for example, approximately 7.5 mm to approximately 16.5 mm, for example, approximately 7.5 mm to approximately 15.5 mm, for example, approximately 7.5 mm to approximately 14.5 mm, for example, approximately 7.5 mm to approximately 13.5 mm, for example, approximately 7.5 mm to approximately 13 mm, for example, approximately 8.5 mm to approximately 27.5 mm, for example, approximately 9.5 mm to approximately 27.5 mm, for example, approximately 10.5 mm to approximately 27.5 mm, for example, approximately 11.5 mm to approximately 27.5 mm, for example, approximately 9.5 mm to approximately 22.5 mm, for example, approximately 10.5 mm to approximately 20.5 mm, for example, approximately 11.5 mm to approximately 17.5 mm, for example, approximately 11.5 mm to approximately 16.5 mm, for example, approximately 11.5 mm to approximately 14.5 mm, for example, approximately 11.5 mm to approximately 13.5 mm, for example, approximately 11.5 mm to approximately 13 mm.

When the shape of the window 102 is circular or oval, and the shapes of the first through hole 101 and the second through hole 201 are circular or oval, the shape of the first region 1102 may also be circular or oval.

When the first region 1102 is circular, the diameter (w3) of the first region 1102 may be larger than the diameter (w5) of the second through hole 201. When the diameter (w3) of the first region 1102 is the same as the diameter (w5) of the second through hole 201, or is smaller than the diameter (w5) of the second through hole 201, this case may be disadvantageous in minimizing the area of a worn region in the light transmission region of the window 102 or substantially preventing wear. As a result, it may be more difficult to maintain the polishing endpoint detection function over a long period of time.

The difference between the diameter (w3) of the first region 1102 and the diameter (w5) of the second through hole 201 may be, for example, approximately 2 mm to approximately 10 mm, for example, approximately 2 mm to approximately 9.5 mm, for example, approximately 2 mm to approximately 9 mm, for example, approximately 2 mm to approximately 8.5 mm, for example, approximately 2 mm to approximately 8 mm, for example, approximately 2.5 mm to approximately 10 mm, for example, 3 mm to approximately 10 mm, for example, approximately 2.5 mm to approximately 9.5 mm, for example, approximately 3 mm to approximately 8.5 mm. When the difference between the diameter (w3) of the first region 1102 and the diameter (w5) of the second through hole 201 is within the above range, the light transmission region of the window 102 may be made to cover the first region 1102 as much as possible. In addition, it may be more advantageous to prevent actual wear of the window 102 or to maximize the effect of maintaining the polishing endpoint detection function for a long time by appropriately adjusting the area ratio of a worn region in the light transmission region even when wear occurs.

In one embodiment, a first adhesive layer 30 may be included between the bottom cross-section of the window 102 and the third surface 21, and a second adhesive layer 40 may be included between the second surface 12 and the third surface 21 and between the bottom cross-section of the window and the third surface 21. The water leak prevention effect may be greatly improved by providing a multi-stage adhesive layer including the first adhesive layer 30 and the second adhesive layer 40 between the bottom cross-section of the window and the third surface 21. Specifically, the polishing process using the polishing pad 100 is performed by supplying a fluid such as liquid slurry onto the first surface 11. At this time, components derived from the fluid may flow into the interface between the side of the window 102 and the side of the first through hole 101. When the fluid components transmitted in this way pass through the second through hole 201 and flow into the polishing device at the bottom of the polishing pad 100, it may cause malfunction of the polishing device or prevent accurate endpoint detection of the window 102. From this perspective, by forming the second through hole 201 smaller than the first through hole 101 in the polishing pad 100, the support surface of the window 102 may be secured on the third surface 21. In addition, the water leak prevention effect may be greatly improved by forming a multi-stage adhesive layer including the first adhesive layer 30 and the second adhesive layer 40 on the support surface.

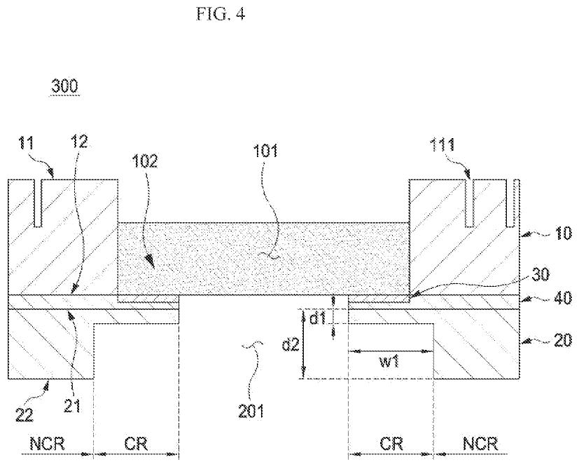

FIG. 4 schematically shows a cross-section in the thickness direction of the window-containing region of a polishing pad 300 according to another embodiment. Referring to FIG. 4, the polishing pad 300 may include a partially compressed region (CR) in the support layer 20. The compressed region (CR) is a part compressed by applying a certain amount of pressure to the bottom cross-section of the support layer 20, and may maximize the water leak prevention effect of the polishing pad 300. The compressed region (CR) is formed in a region corresponding to the bottom cross-section of the window 102 in the support layer 20. The region corresponding to the bottom cross-section of the window 102 refers to a predetermined region including a portion corresponding to the bottom cross-section of the window 102 in the support layer 20, and the lateral extension of the window 102 and the medial end of the compressed region (CR) do not necessarily coincide. That is, the compressed region (CR) is formed on a predetermined region to include all parts corresponding to the bottom cross-section of the window 102 from the side of the second through hole 201 toward the inside of the support layer 20.

The support layer 20 may include a non-compressed region (NCR) in the region excluding the compressed region (CR). The non-compressed region (NCR) has a predetermined porosity, may act as a buffer for preventing external force applied to the polishing pad 100 from being transmitted to a polishing object through a polishing surface 11, and may serve to support the polishing layer 10.

In one embodiment, the compressed region (CR) may have a continuous structure to include all parts corresponding to the bottom cross-section of the window 102 in the direction from the side of the second through hole 201 toward the inside of the support layer. Explained from another perspective, the compressed region (CR) is a continuous compressed region that includes all parts corresponding to the bottom cross-section of the window 102, and may not include more than two compressed regions delimited by the non-compressed region (NCR). Explained from another aspect, the compressed region (CR) may be a continuous compressed region formed to include all parts corresponding to the bottom cross-section of the window 102. That is, the compressed region (CR) is a continuous compressed region formed by pressing from the fourth surface 22 side, which is the lower surface of the support layer 20, and does not include two or more compressed regions with different pressing directions during the formation process. Accordingly, process efficiency may be maximized. In addition, a high-density region formed through a pressurization process may be more advantageous in improving the water leak prevention effect.

In this way, by forming a compressed region (CR) in the region corresponding to the bottom cross-section of the window 102 of the support layer 20, the compressed region (CR) may form a high-density region compared to the non-compressed region (NCR). In this case, fluid components may be effectively prevented from flowing into the interface between the side of the window 102 and the side of the first through hole 101 along with the multi-stage adhesive layer. As a result, in the polishing pad 100 according to one embodiment, the multi-stage adhesive layer structure between the bottom cross-section of the window 102 and the third surface 21 and the compressed region (CR) structure of the support layer 20 are organically combined. Thus, compared to the prior art, the water leak prevention effect may be significantly improved.

In one embodiment, the first adhesive layer 30 may include a moisture-curable resin, and the second adhesive layer 40 may include a thermoplastic resin. In one embodiment, the first adhesive layer 30 and the second adhesive layer 40 may be sequentially arranged in a direction from the bottom cross-section of window 102 toward the third surface 21. The first adhesive layer 30 is an adhesive layer that fluid components that leaks between the side of the window 102 and the side of the first through hole 101 first encounters. By including a moisture-curable resin in the first adhesive layer 30, the water leak prevention effect may be greatly improved. The second adhesive layer 40 is a component of the multi-stage adhesive layer between the bottom cross-section of the window 102 and the third surface 21, and is a layer placed between the second surface 12 and the third surface 21 to attach the polishing layer 10 and the support layer 20. By including a thermoplastic resin in the second adhesive layer 40, the second adhesive layer 40 may be laminated together with the first adhesive layer 30 to improve the water leak prevention effect and at the same time, provide excellent interfacial durability of the polishing layer 10 and the support layer 20.

The first adhesive layer 30 may include a moisture-cured product of a moisture-curable adhesive composition containing a urethane-based prepolymer polymerized from a monomer component containing an aromatic diisocyanate and a polyol. Here, ‘moisture-curable’ refers to the property in which moisture acts as a curing initiator, and the moisture-curable adhesive composition refers to an adhesive composition in which moisture in the air acts as a curing initiator. In this specification, the ‘prepolymer’ refers to a polymer having a relatively low molecular weight in which the degree of polymerization is stopped at an intermediate stage to facilitate molding in the production of a cured product. The prepolymer may be molded into a final cured product after undergoing additional curing processes such as heating and/or pressurizing, or reacting by mixing with additional compounds such as other polymerizable compounds (e.g., heterogeneous monomer or heterogeneous prepolymer).

When the first adhesive layer 30 is derived from a moisture-curable adhesive composition containing a urethane-based prepolymer polymerized from the monomer component, the interfacial adhesion between the window 102 and the first adhesive layer 30 may be greatly improved, and the water leak prevention effect may be greatly improved based on the excellent compatibility of the first adhesive layer 30 and the second adhesive layer 40.

More specifically, the first adhesive layer 30 may include a urethane-based prepolymer formed by polymerization from monomer components containing an aromatic diisocyanate represented by Chemical Formula 1 below and a diol having carbon atoms of 2 to 10; and a moisture-cured product of a moisture-curable adhesive composition including an unreacted aromatic diisocyanate represented by Chemical Formula 1 below.

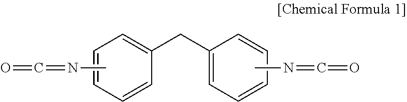

For example, the monomer component may include a diol having 2 to 10 carbon atoms, for example, 3 to 10 carbon atoms, for example, 4 to 10 carbon atoms, and 5 to 10 carbon atoms.

More specifically, the first adhesive layer 30 may include a urethane-based prepolymer obtained by polymerizing monomer components containing the aromatic diisocyanate represented by Chemical Formula 1, a diol represented by Chemical Formula 2 below, and a diol represented by Chemical Formula 3 below; and a moisture-cured product of a moisture-curable adhesive composition containing the unreacted aromatic diisocyanate represented by Chemical Formula 1.

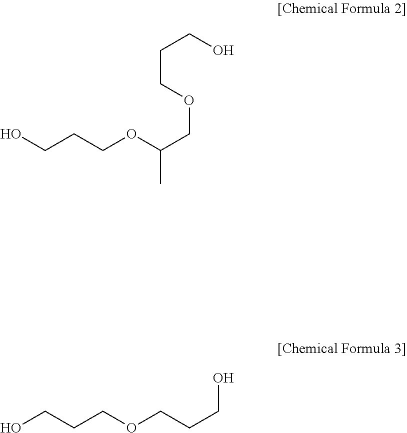

The adhesive composition may include the urethane-based prepolymer in an amount of approximately 90% by weight to approximately 99% by weight and the unreacted aromatic diisocyanate in an amount of approximately 1% by weight to approximately 10% by weight. For example, the adhesive composition may include the urethane-based prepolymer in an amount of approximately 91% by weight to approximately 99% by weight, for example, approximately 93% by weight to approximately 99% by weight, for example, approximately 95% by weight to approximately 99% by weight and the unreacted aromatic diisocyanate in an amount of approximately 1% by weight to approximately 9% by weight, for example, approximately 1% by weight to approximately 7% by weight, for example, approximately 1% by weight to approximately 5% by weight. The unreacted aromatic diisocyanate refers to a diisocyanate in which the isocyanate group (—NCO) at both ends exists without reacting with urethane.

In one embodiment, a moisture-cured product of the moisture-curable adhesive composition may be the result of pressurization and ultrasonic fusion; pressurization and heat fusion; or pressurization, ultrasonic fusion, and heat fusion of the moisture-curable adhesive composition.

The adhesive composition for the first adhesive layer 30 may have a viscosity of approximately 5,000 mPa·s to approximately 10,000 mPa·s, for example, approximately 6,000 mPa·s to approximately 9,000 mPa·s at room temperature. Here, room temperature refers to a temperature within the range of approximately 20° C. to approximately 30° C. When the viscosity of the adhesive composition satisfies this range, excellent process efficiency may be secured during the formation of the first adhesive layer 30. In addition, the density of the first adhesive layer 30 formed by curing the adhesive composition may be more advantageous for the water leak prevention effect.

Specifically, the second adhesive layer 40 may include one selected from the group consisting of a thermoplastic urethane-based adhesive, a thermoplastic acrylic adhesive, a thermoplastic silicon-based adhesive, and combinations thereof. When the second adhesive layer 40 includes a thermoplastic resin, process efficiency may be improved compared to the case where the second adhesive layer 40 includes thermosetting resin. Specifically, when a thermosetting adhesive is used as the second adhesive layer 40, the efficiency of mass production may be reduced due to difficulties in applying the roll-to-roll process. In addition, since a spray application method must be used instead of roll-to-roll, there is a risk that pad contamination due to scattering may increase. That is, the second adhesive layer 40 is a large-area layer formed between the second surface 12 and the third surface 21. By applying a thermoplastic adhesive, process efficiency may be increased, defect rate may be significantly reduced by preventing polishing pad contamination, and excellent compatibility may be secured in terms of securing the water leak prevention effect with the first adhesive layer 40 derived from a moisture-curing adhesive.

Referring to FIG. 4, the percentage of the thickness (d1) of the compressed region (CR) compared to the thickness (d2) of the non-compressed region (NCR) may be approximately 0.01% to approximately 80%, for example, approximately 0.01% to approximately 60%, for example, approximately 0.01% to approximately 50%, for example, approximately 0.1% to approximately 50%, for example, approximately 1% to approximately 50%, for example, approximately 1% to approximately 45%, for example, approximately 2% to approximately 45%, for example, approximately 5% to approximately 45%, for example, approximately 10% to approximately 45%, for example, approximately 15% to approximately 45%, for example, approximately 20% to approximately 45%. That is, the value of d1/d2×100 may satisfy the range. When the compressed region (CR) is compressed to have a thickness that satisfies the percentage of the range compared to the thickness of the non-compressed region (NCR), together with the multi-stage adhesive layer structure of the bottom cross-section of the window 102, it may be more advantageous to improve the water leak prevention effect. In addition, the compressed region (CR) may form a high-density region that is effective in preventing water leakage without impairing the buffering and support functions of the non-compressed region (NCR).

The percentage of thickness (d1) of the compressed region (CR) compared to the width (w1) of the compressed region (CR) may be approximately 0.01% to approximately 30%, for example, approximately 0.01% to 20%, for example, approximately 0.1% to approximately 20%, for example, approximately 1% to approximately 20%, for example, approximately 1% to approximately 15%, for example, approximately 2% to approximately 15%, for example, approximately 2% to approximately 10%, for example, approximately 3% to approximately 9%. When the thickness (d1) of the compressed region (CR) satisfies the ratio compared to the width (w1), the compressed region (CR) region may achieve an optimal water leak prevention effect without compromising the overall support ability of the support layer 20 for the polishing layer 10 and the window 102.

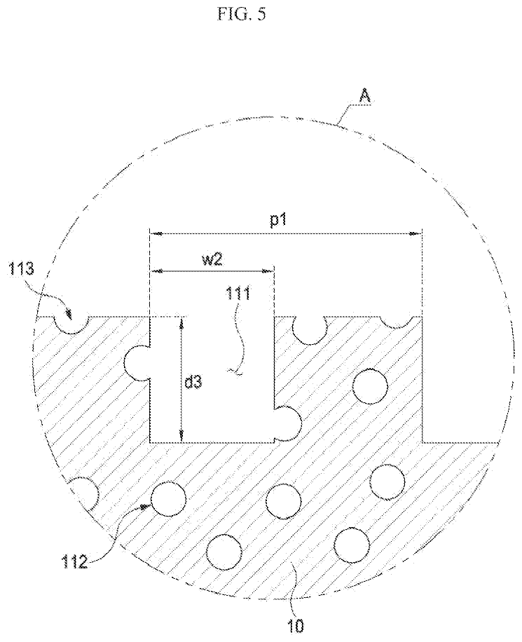

FIG. 5 is an enlarged schematic diagram of part A of FIG. 1. Referring to FIG. 5, the first surface 11 may include at least one groove 111. The groove 111 is a groove structure processed with a depth (d3) smaller than the thickness (d4) of the polishing layer 10, and may perform the function of ensuring the fluidity of liquid components such as polishing slurry and cleaning fluid applied to the first surface 11 during the polishing process. The fluidity of the polishing slurry applied to the first surface 11 is closely related to the water leakage phenomenon through the boundary between the window 102 and the polishing layer 10 and/or the occurrence of scratches on the polishing target surface caused by the boundary between the window 102 and the polishing layer 10. When the fluidity of the polishing slurry is not appropriate, debris from the polishing slurry may remain at the border between the window 102 and the polishing layer 10, causing scratches on the polishing target surface of a polishing object. In addition, the debris may cause excessive wear of the surface of the window 102, rapidly reducing the light transmittance of the window 102 and causing loss of the polishing endpoint detection function. Accordingly, by appropriately designing the structure of the groove 111, the water leak prevention effect of the polishing pad 100 and the light transmission performance maintenance effect of the window 102 may be maximized.

In one embodiment, the planar structure of the polishing pad 100 may be substantially circular, and the groove 111 may have a concentric circular structure spaced at a predetermined distance from the center of the polishing layer 10 on the first surface 11 toward the end of the polishing layer 10. In another embodiment, the groove 111 may have a radial structure formed continuously from the center of the polishing layer 10 on the first surface 11 toward the end. In another embodiment, the groove 111 may simultaneously include the concentric circular structure and the radial structure.

In one embodiment, the thickness (d4) of the polishing layer 10 may be approximately 0.8 mm to approximately 5.0 mm, for example, approximately 1.0 mm to approximately 4.0 mm, for example, approximately 1.0 mm to 3.0 mm, for example, approximately 1.5 mm to approximately 3.0 mm, for example, approximately 1.7 mm to approximately 2.7 mm, for example, approximately 2.0 mm to approximately 3.5 mm.

In one embodiment, the width (w2) of the groove 111 may be approximately 100 μm to approximately 1500 μm, for example, approximately 200 μm to approximately 1400 μm, for example, approximately 300 μm to approximately 1300 μm, for example, approximately 400 μm to approximately 1200 μm, for example, approximately 400 μm to approximately 1000 μm, for example, approximately 400 μm to approximately 800 μm.

In one embodiment, the depth (d3) of the groove 111 may be approximately 0.1 mm to approximately 20 mm, for example, approximately 0.1 mm to approximately 15 mm, for example, approximately 0.1 mm to approximately 10 mm, for example, approximately 0.1 mm to approximately 5 mm, for example, approximately 0.1 mm to approximately 1.5 mm.

In one embodiment, when the first surface 11 includes a plurality of grooves 111 and the grooves 111 include concentric circular grooves, the pitch (p1) between the two adjacent grooves 111 of the concentric circular grooves may be approximately 2 mm to approximately 70 mm, for example, approximately 2 mm to approximately 60 mm, for example, approximately 2 mm to approximately 50 mm, for example, approximately 2 mm to approximately 35 mm, for example, approximately 2 mm to approximately 10 mm, for example, approximately 2 mm to approximately 8 mm.

When the at least one groove 111 satisfies the depth (d3), the width (w2), and the pitch (p1) within the above ranges, respectively or simultaneously, the fluidity of polishing slurry implemented through the groove 111 may be more advantageous in maximizing the light transmittance maintenance performance and water leak prevention effect of the window 102. Specifically, when the depth (d3), width (w2), and pitch (p1) of the groove 111 are outside the above-mentioned ranges, when the fluidity of polishing slurry implemented through the groove 111 is too high or the flow rate per unit time is too high, the polishing slurry component may not perform the original polishing function thereof and may be discharged outside the first surface 11. Conversely, when the fluidity of the polishing slurry is too low or the flow rate per unit time is too low, the polishing slurry component may not perform the original polishing function thereof and may remain on the surface of the window 102 through the boundary between the window 102 and the polishing layer 10, causing excessive wear of the surface of the window 102.

Referring to FIG. 5, the polishing layer 10 may have a porous structure including a plurality of pores 112. The pores 112 are dispersed throughout the polishing layer 10, and may continuously play the role of creating a certain roughness on the surface even when the first surface 11 is ground by a conditioner during the polishing process. Some of the pores 112 may be exposed to the outside on the first surface 11 and may appear as a fine concave portion 113 that is distinct from the groove 111. The fine concave portion 113 may perform the function of determining the fluidity and retention space of a polishing solution or polishing slurry together with the groove 111 during use of the polishing pad 100, and may perform the function of physically providing friction when polishing the polishing target surface of a polishing object.

The average pore size of the pores 112 may be approximately 10 μm to approximately 30 μm, for example, approximately 10 μm to approximately 25 μm, for example, approximately 15 μm to approximately 25 μm, for example, approximately 18 μm to approximately 23 μm. The polishing pad was cut into 1 mm×1 mm squares (thickness: 2 mm) to obtain 1 mm² fragments. An image of the polished surface of the fragment was obtained at 100 times magnification using a scanning electron microscope (SEM). Based on the image, a cross-section was observed, and the diameters and number of pores were measured from images obtained using image analysis software. The average size of the pores is a number average value obtained by dividing the sum of the diameters of pores within 1 mm² of the polishing surface by the number of pores. The polishing layer 10 may have appropriate mechanical properties by having a porous structure composed of a plurality of pores that satisfy the average pore size. These mechanical properties show excellent compatibility with the mechanical and physical properties of the window 102, which may be more advantageous in maintaining the light transmission performance of the window 102 for a long time.

The first surface 11 may have a predetermined surface roughness due to the fine concave portion 113. In one embodiment, the surface roughness (Ra) of the first surface 11 may be approximately 1 μm to approximately 20 μm, for example, approximately 2 μm to approximately 18 μm, for example, approximately 3 μm to approximately 16 μm, for example, approximately 4 μm to approximately 14 μm, for example, approximately 4 μm to approximately 10 μm. When the surface roughness (Ra) of the first surface 11 satisfies the range, the fluidity of the polishing slurry due to the fine concave portion 113 may be more advantageous in preventing surface wear of the window 102, and may be more advantageous in preventing leakage through the boundary between the window 102 and the polishing layer 10.

In one embodiment, the Shore D hardness measured under a room temperature dry condition for the first surface 11 may be smaller than the Shore D hardness measured under a room temperature dry condition for the top cross-section of the window 102. Here, the room temperature dry condition means a dry state without processing the wet condition described later under a temperature condition within the range of approximately 20° C. to approximately 30° C. For example, the difference between the Shore D hardness measured under the room temperature dry condition for the first surface 11 and the Shore D hardness measured under the room temperature dry condition for the top cross-section of the window 102 may be approximately 5 to approximately 10, for example, approximately 5 to approximately 7, for example, approximately 5.5 to approximately 6.5.

In one embodiment, the Shore D hardness measured under the room temperature dry condition for the top cross-section of the window 102 may be approximately 60 to approximately 70, for example, approximately 60 to 68, for example, approximately 60 to approximately 65.

In one embodiment, the difference between the Shore D wet hardness measured at 30° C. for the top cross-section of the window 102 and the Shore D wet hardness measured under the room temperature dry condition for the top cross-section of the window 102 may be approximately 0 to approximately 1.0, for example, approximately 0 to approximately 0.8.

In one embodiment, the Shore D wet hardness measured at 50° C. for the top cross-section of the window 102 may be less than the Shore D wet hardness measured under the room temperature dry condition for the top cross-section of the window 102. For example, the difference between the Shore D wet hardness measured at 50° C. for the top cross-section of the window 102 and the Shore D wet hardness measured under the room temperature dry condition for the top cross-section of the window 102 may be approximately 1 to approximately 7, for example, approximately 1 to approximately 6, for example, approximately 1 to 5.5.

In one embodiment, the Shore D wet hardness measured at 70° C. for the top cross-section of the window 102 may be less than the Shore D wet hardness measured under the room temperature dry condition for the top cross-section of the window 102. For example, the difference between the Shore D wet hardness measured at 70° C. for the top cross-section of the window 102 and the Shore D wet hardness measured under the room temperature dry condition for the top cross-section of the window 102 may be approximately 5 to approximately 10, for example, approximately 6 to approximately 10, for example, approximately 7 to 10.

In one embodiment, the Shore D wet hardness measured at 30° C. for the first surface 11 may be less than the Shore D wet hardness measured at 30° C. for the top cross-section of the window 30. For example, the difference between the Shore D wet hardness measured at 30° C. for the first surface 11 and the Shore D wet hardness measured at 30° C. for the top cross-section of the window 30 may be greater than approximately 0 and approximately 15 or less, for example, approximately 1 to approximately 15, for example, approximately 2 to approximately 15.

In one embodiment, the Shore D wet hardness measured at 50° C. for the first surface 11 may be less than the Shore D wet hardness measured at 50° C. for the top cross-section of the window 30. For example, the difference between the Shore D wet hardness measured at 50° C. for the first surface 11 and the Shore D wet hardness measured at 50° C. for the top cross-section of the window 30 may be greater than approximately 0 and approximately 15 or less, for example, approximately 1 to approximately 25, for example, approximately 5 to approximately 25, for example, approximately 5 to 15.

In one embodiment, the Shore D wet hardness measured at 70° C. for the first surface 11 may be less than the Shore D wet hardness measured at 70° C. for the top cross-section of the window 30. For example, the difference between the Shore D wet hardness measured at 70° C. for the first surface 11 and the Shore D wet hardness measured at 70° C. for the top cross-section of the window 30 may be greater than approximately 0 and approximately 15 or less, for example, approximately 1 to approximately 25, for example, approximately 5 to approximately 25, for example, approximately 8 to 16.

Here, the Shore D wet hardness is a surface hardness value measured after immersing the window 30 or the polishing layer 10 in water at the corresponding temperature for 30 minutes.

The polishing process in which the polishing pad 100 is used is a process of performing polishing while applying liquid slurry on the first surface 11. In addition, the temperature of the polishing process may vary from approximately 30° C. to approximately 70° C. That is, when the change in hardness of the top cross-section of the window 102, derived based on Shore D hardness measured under a temperature and wet environment similar to the actual process, satisfies the aforementioned tendency, and the hardness relationship between the first surface 11 and the top cross-section of the window 102 under the room temperature dry condition satisfies the above-mentioned range, while polishing is in progress throughout the top cross-section of the window 102 and the first surface 11, the polishing operation may proceed smoothly, so the value of Equation 1 of the window 102 is advantageous for implementing the target range. As a result, the polishing endpoint detection function the window may be maintained excellently for a long time.

In one embodiment, the window 102 may include a non-foamed cured product of a window composition containing a first urethane-based prepolymer. Since the window 102 includes the non-foamed cured product, Compared to the case of containing a foamed cured product, it may be more advantageous to secure the light transmittance and appropriate surface hardness required for endpoint detection. The ‘prepolymer’ refers to a polymer with a relatively low molecular weight obtained by stopping the degree of polymerization at an intermediate stage to facilitate molding in the production of cured products. The prepolymer may be subjected to an additional curing process such as heating and/or pressurization, or may be mixed and reacted with additional compounds such as other polymerizable compounds, for example, heterogeneous monomers or heterogeneous prepolymers, and then molded into a final cured product.

The first urethane-based prepolymer may be prepared by reacting a first isocyanate compound and a first polyol compound. The first isocyanate compound may include one selected from the group consisting of aromatic diisocyanates, aliphatic diisocyanates, alicyclic diisocyanates, and combinations thereof. In one embodiment, the first isocyanate compound may include an aromatic diisocyanate and an alicyclic diisocyanate.

For example, the first isocyanate compound may include one selected from the group consisting of 2,4-toluenediisocyanate (2,4-TDI), 2,6-toluenediisocyanate (2,6-TDI), naphthalene-1,5-diisocyanate, p-phenylene diisocyanate, tolidine diisocyanate, 4,4′-diphenylmethane diisocyanate, hexamethylene diisocyanate, dicyclohexylmethane diisocyanate, 4,4′-dicyclohexylmethane diisocyanate (H₁₂MDI), isoporone diisocyanate, and combinations thereof.

For example, the first polyol compound may include one selected from the group consisting of polyether polyols, polyester polyols, polycarbonate polyols, acryl polyols, and combinations thereof. The ‘polyol’ refers to a compound containing at least two hydroxy groups (—OH) per molecule. In one embodiment, the first polyol compound may include a dihydric alcohol compound with two hydroxy groups, that is, a diol or a glycol. In one embodiment, the first polyol compound may include a polyether polyol.

For example, the first polyol compound may include one selected from the group consisting of polytetramethylene ether glycol (PTMG), polypropylene ether glycol, ethylene glycol, 1,2-propyleneglycol, 1,3-propylene glycol, 1,2-butanediol, 1,3-butanediol, 2-methyl-1,3-propanediol, 1,4-butanediol, neopentyl glycol, 1,5-pentanediol, 3-methyl-1,5-pentanediol, 1,6-hexanediol, diethylene glycol (DEG), dipropylene glycol (DPG), tripropylene glycol, polypropylene glycol (PPG), and combinations thereof.

In one embodiment, the weight average molecular weight (Mw) of the first polyol compound may be approximately 100 g/mol to approximately 3,000 g/mol, for example, approximately 100 g/mol to approximately 2,000 g/mol, for example, approximately 100 g/mol to approximately 1,800 g/mol, for example, approximately 500 g/mol to approximately 1,500 g/mol, for example, approximately 800 g/mol to approximately 1,200 g/mol.

In one embodiment, the first polyol compound may include a low molecular weight polyol with a weight average molecular weight (Mw) of approximately 100 g/mol or more and less than approximately 300 g/mol and a high molecular weight polyol with a weight average molecular weight (Mw) of approximately 300 g/mol or more and approximately 1800 g/mol or less. By appropriately mixing the low molecular weight polyol and high molecular weight polyol with weight average molecular weights within the ranges as the first polyol compound, a non-foamed cured product with an appropriate cross-linked structure may be formed from the first urethane-based prepolymer, and the window 102 may be more advantageous in securing the desired physical properties such as hardness and optical properties such as light transmittance.

The weight average molecular weight (Mw) of the first urethane-based prepolymer may be approximately 500 g/mol to approximately 2000 g/mol, for example, approximately 800 g/mol to approximately 1500 g/mol, for example, approximately 900 g/mol to approximately 1200 g/mol, for example, approximately 950 g/mol to approximately 1100 g/mol. When the first urethane-based prepolymer has a degree of polymerization corresponding to the weight average molecular weight (Mw) in the aforementioned range, it may be advantageous for the window composition to be foam-free cured under a predetermined process condition to form the window 102 having an appropriate mutual surface hardness relationship with the polishing surface of the polishing layer 10. Accordingly, polishing progresses smoothly across the polishing surface and the entire top cross-section of the window 102, thereby preventing water leakage.

In one embodiment, the first isocyanate compound may include an aromatic diisocyanate and an alicyclic diisocyanate. For example, the aromatic diisocyanate may include 2,4-toluenediisocyanate (2,4-TDI) and 2,6-toluenediisocyanate (2,6-TDI), and the alicyclic diisocyanate may include dicyclohexylmethane diisocyanate (H₁₂MDI). In addition, the first polyol compound may include, for example, polytetramethylene ether glycol (PTMG), diethylene glycol (DEG), and polypropyleneglycol (PPG).

In the window composition, based on 100 parts by weight in total of the first isocyanate compound among all components for preparing the first urethane-based prepolymer, the total amount of the first polyol compound may be approximately 100 parts by weight to approximately 250 parts by weight, for example, approximately 120 parts by weight to approximately 250 parts by weight, for example, approximately 120 parts by weight to approximately 240 parts by weight, for example, approximately 150 parts by weight to approximately 240 parts by weight, for example, approximately 150 parts by weight to approximately 200 parts by weight.

In the window composition, the first isocyanate compound may include the aromatic diisocyanate, and the aromatic diisocyanate may include 2,4-TDI and 2,6-TDI. Based on 100 parts by weight of 2,4-TDI, the amount of 2,6-TDI may be approximately 1 part by weight to approximately 40 parts by weight, for example, approximately 1 part by weight to approximately 30 parts by weight, for example, approximately 10 parts by weight to approximately 30 parts by weight, for example, approximately 15 parts by weight to approximately 30 parts by weight.

In the window composition, the first isocyanate compound may include the aromatic diisocyanate and the alicyclic diisocyanate. Based on 100 parts by weight in total of the aromatic diisocyanate, the amount of the alicyclic diisocyanate may be approximately 5 parts by weight to approximately 30 parts by weight, for example, approximately 10 parts by weight to approximately 30 parts by weight, for example, approximately 15 parts by weight to approximately 30 parts by weight.

When the relative content ratio of each component of the window composition satisfies the above-mentioned range individually or simultaneously, the window 102 manufactured using the window composition may secure light transmittance necessary for the endpoint detection function, and at the same time, the top cross-section of the window 102 may have appropriate surface hardness. Accordingly, the top cross-section of the window 102 may form an appropriate mutual surface hardness relationship with the polishing surface of the polishing layer 10 manufactured from a polishing layer composition in which the relative content ratio of each component satisfies the range described later individually or simultaneously. By facilitating polishing that proceeds repeatedly through the polishing surface and the window top cross-section, the polishing endpoint detection function of the window 102 may be maintained for a long time.

The isocyanate group content (NCO %) of the window composition may be approximately 6% by weight to approximately 10% by weight, for example, approximately 7% by weight to approximately 9% by weight, for example, approximately 7.5% by weight to approximately 8.5% by weight. The isocyanate group content refers to the percentage of the weight of the isocyanate group (—NCO) that is not reacted with urethane and exists as a free reaction group in the total weight of the window composition. The isocyanate group content may be designed by controlling the type and content of the first isocyanate compound and first polyol compound for preparing the first urethane-based prepolymer, conditions including temperature, pressure, and time for the process of preparing the first urethane-based prepolymer, and the types and contents of additives used in the preparation of the first urethane-based prepolymer. When the isocyanate group content of the window composition satisfies the range, the window composition may be cured without foaming to ensure appropriate surface hardness. In addition, in terms of maximizing the water leak prevention effect, it may be advantageous to ensure an appropriate hardness correlation with the polishing layer.

The window composition may further include a hardener. The hardener is a compound that chemically reacts with the first urethane-based prepolymer to form a final hardened structure within the window, and may include, for example, an amine compound or an alcohol compound. Specifically, the hardener may include one selected from the group consisting of aromatic amines, aliphatic amines, aromatic alcohols, aliphatic alcohols, and combinations thereof.

For example, the hardener may include one selected from the group consisting of 4,4′-methylenebis(2-chloroaniline) (MOCA), diethyltoluenediamine (DETDA), diaminodiphenylmethane, dimethyl thio-toluene diamine (DMTDA), propanediol bis p-aminobenzoate, methylene bis-methylanthranilate, diaminodiphenylsulfone, m-xylylenediamine, isophoronediamine, ethylenediamine, diethylenetriamine, triethylenetetramine, polypropylenediamine, polypropylenetriamine, bis(4-amino-3-chlorophenyl)methane, and combinations thereof.

Based on 100 parts by weight of the window composition, the content of the hardener may be approximately 18 parts by weight to approximately 28 parts by weight, for example, approximately 19 parts by weight to approximately 27 parts by weight, for example, approximately 20 parts by weight to approximately 26 parts by weight.

In one embodiment, the hardener may include an amine compound. The molar ratio of an isocyanate group (—NCO) in the window composition to an amine group (—NH₂) in the hardener may be approximately 1:0.60 to approximately 1:0.99, for example, approximately 1:0.60 to approximately 1:0.95.

As described above, the window may include a non-foamed cured product of the window composition. Accordingly, the window composition may not include a foaming agent. As the window composition undergoes a curing process without a foaming agent, light transparency required for end point detection may be secured.

The window composition may include optionally additives when necessary. The additive may include one selected from the group consisting of surfactants, pH adjusters, binders, antioxidants, heat stabilizers, dispersion stabilizers, and combinations thereof. Names such as ‘surfactant’ and ‘antioxidant’ above are arbitrary names based on the main role of the substance, and each substance does not necessarily perform only the functions limited to the role under the name.

In one embodiment, in the window 102, light transmittance for light with one wavelength in the wavelength range of approximately 500 nm to approximately 700 nm for a thickness of 2 mm before applying the polishing process may be approximately 1% to approximately 50%, for example, approximately 30% to approximately 85%, for example, approximately 30% to approximately 70%, for example, approximately 30% to approximately 60%, for example, approximately 1% to approximately 20%, for example, approximately 2% to approximately 20%, for example, approximately 4% to approximately 15%.

In one embodiment, in the window 102, light transmittance for light with a wavelength of 450 nm after polishing for 20 hours for a thickness of 2 mm under Condition 1 may be approximately 10% or more, for example, approximately 10% to approximately 50%, for example, approximately 10% or more and less than approximately 50%, for example, approximately 10% to approximately 48%, for example, approximately 10% to approximately 46%, for example, approximately 10% to approximately 40%, for example, approximately 10% to approximately 35%, for example, approximately 10% to approximately 30%, for example, approximately 10% to approximately 28%, for example, approximately 10% to approximately 25%. That is, with the first surface 11 and the polishing target surface of the silicon wafer arranged to face each other, after performing polishing for 20 hours under the conditions that a rotation speed of the silicon wafer is 87 rpm, a rotation speed of the polishing pad 100 is 93 rpm, a pressing load of the polishing target surface of the silicon wafer against the first surface 11 is 3.5 psi, the flow rate of distilled water injected onto the first surface 11 is 200 mL/min, the rotation speed of a conditioner that processes the first surface 11 is 101 rpm, and the vibration movement speed of the conditioner is 19 times/min, light transmittance for a thickness of 2 mm and light with a wavelength of 450 nm may satisfy the range. Condition 1 is a measurement condition that may produce highly reliable experimental results by matching the experimentally expected maintenance performance of the polishing endpoint detection function with the maintenance performance of the polishing endpoint detection function in the actual polishing process. That is, experimental results obtained by conducting a polishing experiment under measurement conditions other than Condition 1 may be meaningless experimental results because the results do not correspond to the maintenance performance of the polishing endpoint detection function of the window in the actual polishing process. When the light transmittance of the window 102 satisfies the range after polishing for 20 hours under Condition 1, the polishing pad 100 equipped with the window 102 may maintain excellent polishing endpoint detection function for a long time during the actual polishing process.

In one embodiment, after polishing for a time under Condition 1 using the polishing pad 100, when the light transmittance of the window 102 for light with a wavelength of 450 nm is 2.5% or less, the α may be approximately 50 or more, for example, approximately 50 to approximately 120, for example, approximately 50 to approximately 100. That is, after polishing is performed using the polishing pad 100 under Condition 1 for approximately 50 hours or more, for example, approximately 50 hours to approximately 120 hours, for example, approximately 50 hours to approximately 100 hours, the light transmittance of the window 102 for light with a wavelength of a 450 nm may be approximately 2.5% or less. Condition 1 is a measurement condition that may produce highly reliable experimental results by matching the experimentally expected maintenance performance of the polishing endpoint detection function with the maintenance performance of the polishing endpoint detection function in the actual polishing process. That is, experimental results obtained by conducting a polishing experiment under measurement conditions other than Condition 1 may be meaningless experimental results because the results do not correspond to the maintenance performance of the polishing endpoint detection function of the window in the actual polishing process. When polishing is performed under Condition 1, when the polishing time, which reduces the light transmittance of the window 102 to approximately 2.5% or less, satisfies the range, when the polishing pad 100 is applied to the actual polishing process, the retention time of the polishing endpoint detection function may be maximized, resulting in a greatly increased lifespan of the polishing pad 100.

In one embodiment, the polishing layer 10 may include a foamed cured product of a polishing layer composition containing a second urethane-based prepolymer. The polishing layer 10 may have a pore structure by including the foamed cured product. This pore structure may form surface roughness on a polishing surface, which cannot be formed with non-foamed cured products, and may function to appropriately secure the fluidity of polishing slurry applied to the polishing surface and physical friction with the polishing target surface of a polishing object. The ‘prepolymer’ refers to a polymer with a relatively low molecular weight obtained by stopping the degree of polymerization at an intermediate stage to facilitate molding in the production of cured products. The prepolymer may be subjected to an additional curing process such as heating and/or pressurization, or may be mixed and reacted with additional compounds such as other polymerizable compounds, for example, heterogeneous monomers or heterogeneous prepolymers, and then molded into a final cured product.

The second urethane-based prepolymer may be prepared by reacting a second isocyanate compound and a second polyol compound. The second isocyanate compound may include one selected from the group consisting of aromatic diisocyanates, aliphatic diisocyanates, alicyclic diisocyanates, and combinations thereof. In one embodiment, the second isocyanate compound may include an aromatic diisocyanate. For example, the second isocyanate compound may include an aromatic diisocyanate and an alicyclic diisocyanate.

For example, the second isocyanate compound may include one selected from the group consisting of 2,4-toluenediisocyanate (2,4-TDI), 2,6-toluenediisocyanate (2,6-TDI) naphthalene-1,5-diisocyanate, p-phenylene diisocyanate, tolidine diisocyanate, 4,4′-diphenylmethane diisocyanate, hexamethylene diisocyanate, dicyclohexylmethane diisocyanate, 4,4′-dicyclohexylmethane diisocyanate (H₁₂MDI), isoporone diisocyanate, and combinations thereof.

For example, the second polyol compound may include one selected from the group consisting of polyether polyols, polyester polyols, polycarbonate polyols, acryl polyols, and combinations thereof. The ‘polyol’ refers to a compound containing at least two hydroxy groups (—OH) per molecule. In one embodiment, the second polyol compound may include a dihydric alcohol compound with two hydroxy groups, that is, a diol or a glycol. In one embodiment, the second polyol compound may include a polyether polyol.

For example, the second polyol compound may include one selected from the group consisting of polytetramethylene ether glycol (PTMG), polypropylene ether glycol, ethylene glycol, 1,2-propyleneglycol, 1,3-propylene glycol, 1,2-butanediol, 1,3-butanediol, 2-methyl-1,3-propanediol, 1,4-butanediol, neopentyl glycol, 1,5-pentanediol, 3-methyl-1,5-pentanediol, 1,6-hexanediol, diethylene glycol (DEG), dipropyleneglycol (DPG), tripropyleneglycol, polypropyleneglycol (PPG), and combinations thereof.

In one embodiment, the second polyol compound may include a low molecular weight polyol having a weight average molecular weight (Mw) of approximately 100 g/mol or more and less than approximately 300 g/mol and a high molecular weight polyol having a weight average molecular weight (Mw) of approximately 300 g/mol to approximately 1800 g/mol. By appropriately mixing the low molecular weight polyol and high molecular weight polyol with weight average molecular weights within the ranges as the second polyol compound, a foamed cured product with an appropriate cross-linked structure may be formed from the second urethane-based prepolymer, and the polishing layer 10 may be more advantageous in forming a foam structure with desired physical properties such as hardness and pores of appropriate size.

The weight average molecular weight (Mw) of the second urethane-based prepolymer may be approximately 500 g/mol to approximately 3,000 g/mol, for example, approximately 600 g/mol to approximately 2,000 g/mol, for example, approximately 800 g/mol to approximately 1,000 g/mol. When the second urethane-based prepolymer has a degree of polymerization corresponding to the weight average molecular weight (Mw) in the aforementioned range, the polishing layer composition may be foamed and cured under predetermined process conditions, so that the polishing layer 10 having a polishing surface having an appropriate mutual surface hardness relationship with the top cross-section of the window 102 may be easily formed. Accordingly, polishing progresses smoothly across the polishing surface and the entire top cross-section of the window 102, thereby minimizing wear of the window 102. In addition, even when wear of the window 102 progresses, the wear area in the entire light transmission region does not exceed an appropriate range, so excellent polishing endpoint detection function may be maintained through the window 102 for a long time.

In one embodiment, the second isocyanate compound may include an aromatic diisocyanate and an alicyclic diisocyanate. For example, the aromatic diisocyanate may include 2,4-toluenediisocyanate (2,4-TDI) and 2,6-toluenediisocyanate (2,6-TDI), and the alicyclic diisocyanate may include dicyclohexylmethane diisocyanate (H₁₂MDI). In addition, the second polyol compound may include, for example, polytetramethylene ether glycol (PTMG) and diethylene glycol (DEG).

In the polishing layer composition, based on 100 parts by weight in total of the second isocyanate compound among all components for preparing the second urethane-based prepolymer, the total amount of the second polyol compound may be approximately 100 parts by weight to approximately 250 parts by weight, for example, approximately 110 parts by weight to approximately 250 parts by weight, for example, approximately 110 parts by weight to approximately 240 parts by weight, for example, approximately 110 parts by weight to approximately 200 parts by weight, for example, approximately 110 parts by weight to approximately 180 parts by weight, for example, approximately 110 parts by weight or more and less than approximately 150 parts by weight.

In the polishing layer composition, the second isocyanate compound may include the aromatic diisocyanate, and the aromatic diisocyanate may include 2,4-TDI and 2,6-TDI. Based on 100 parts by weight of 2,4-TDI, the amount of 2,6-TDI may be approximately 1 part by weight to approximately 40 parts by weight, for example, approximately 1 part by weight to approximately 30 parts by weight, for example, approximately 10 parts by weight to approximately 30 parts by weight, for example, approximately 15 parts by weight to approximately 30 parts by weight.

In the polishing layer composition, the second isocyanate compound may include the aromatic diisocyanate and the alicyclic diisocyanate. Based on 100 parts by weight in total of the aromatic diisocyanate, the total amount of the alicyclic diisocyanate may be approximately 5 parts by weight to approximately 30 parts by weight, for example, approximately 5 parts by weight to approximately 25 parts by weight, for example, approximately 5 parts by weight to approximately 20 parts by weight, for example, approximately 5 parts by weight or more and less than approximately 15 parts by weight.

When the relative content ratio of each component of the polishing layer composition satisfies the above-mentioned range individually or simultaneously, the polishing surface of the polishing layer 10 prepared from the polishing layer composition may have an appropriate pore structure and surface hardness. Accordingly, the polishing surface of the polishing layer 10 may form an appropriate mutual surface hardness relationship with the top cross-section of the window 102 in which the relative content ratio of each component satisfies the above-described range individually or simultaneously. Accordingly, polishing progresses smoothly across the polishing surface and the entire top cross-section of the window 102, thereby minimizing wear of the window 102. In addition, even when wear of the window 102 progresses, the wear area in the entire light transmission region does not exceed an appropriate range, so excellent polishing endpoint detection function may be maintained through the window 102 for a long time.

The isocyanate group content (NCO %) of the polishing layer composition may be approximately 6% by weight to approximately 12% by weight, for example, approximately 6% by weight to approximately 10% by weight, for example, approximately 6% by weight to approximately 9% by weight. The isocyanate group content refers to the percentage of the weight of the isocyanate group (—NCO) that is not reacted with urethane and exists as a free reaction group in the total weight of the preliminary composition. The isocyanate group content may be designed by controlling the type and content of the second isocyanate compound and second polyol compound for preparing the second urethane-based prepolymer, conditions including temperature, pressure, and time for the process of preparing the second urethane-based prepolymer, and the types and contents of additives used in the preparation of the second urethane-based prepolymer. When the isocyanate group content of the polishing layer composition satisfies the range, the polishing layer composition may be foamed and cured under predetermined process conditions, so that the polishing layer 10 having a polishing surface having an appropriate mutual surface hardness relationship with the top cross-section of the window 102 may be easily formed. Accordingly, polishing progresses smoothly across the polishing surface and the entire top cross-section of the window 102, thereby minimizing wear of the window 102. In addition, even when wear of the window 102 progresses, the wear area in the entire light transmission region does not exceed an appropriate range, so excellent polishing endpoint detection function may be maintained through the window 102 for a long time.

The polishing layer composition may further include a hardener. The hardener is a compound that chemically reacts with the second urethane-based prepolymer to form a final hardened structure within the polishing layer, and may include, for example, an amine compound or an alcohol compound. Specifically, the hardener may include one selected from the group consisting of aromatic amines, aliphatic amines, aromatic alcohols, aliphatic alcohols, and combinations thereof.

For example, the hardener may include one selected from the group consisting of 4,4′-methylenebis(2-chloroaniline) (MOCA), diethyltoluenediamine (DETDA), diaminodiphenylmethane, dimethyl thio-toluene diamine (DMTDA), propanediol bis p-aminobenzoate, methylene bis-methylanthranilate, diaminodiphenylsulfone, m-xylylenediamine, isophoronediamine, ethylenediamine, diethylenetriamine, triethylenetetramine, polypropylenediamine, polypropylenetriamine, bis(4-amino-3-chlorophenyl)methane, and combinations thereof.

Based on 100 parts by weight of the polishing layer composition, the content of the hardener may be approximately 18 parts by weight to approximately 28 parts by weight, for example, approximately 19 parts by weight to approximately 27 parts by weight, for example, approximately 20 parts by weight to approximately 26 parts by weight.

In one embodiment, the hardener may include an amine compound. The molar ratio of an isocyanate group (—NCO) in the polishing layer composition to an amine group (—NH₂) in the hardener may be approximately 1:0.60 to approximately 1:0.99, for example, approximately 1:0.60 to approximately 1:0.95.

The polishing layer composition may further include a foaming agent. The foaming agent is an component that forms a pore structure within the polishing layer, and may include one selected from the group consisting of a solid foaming agent, a vapor foaming agent, a liquid foaming agent, and a combination thereof. In one embodiment, the foaming agent may include a solid foaming agent, a vapor foaming agent, or a combination thereof.

The average particle diameter of the solid foaming agent may be approximately 5 μm to approximately 200 μm, for example, approximately 20 μm to approximately 50 μm, for example, approximately 21 μm to approximately 50 μm, for example, approximately 21 μm to approximately 40 μm. When the solid foaming agent is a thermally expanded particle as described below, the average particle diameter of the solid foaming agent means the average particle diameter of the thermally expanded particle. When the solid foaming agent is an unexpanded particle as described below, the average particle diameter of the solid foaming agent means the average particle diameter of particles after expansion by heat or pressure.

The solid foaming agent may include expandable particles. The expandable particles are particles that expand due to heat or pressure. The size of the expandable particles in the final polishing layer may be determined by heat or pressure applied during the process of forming the polishing layer. The expandable particles may include thermally expanded particles, unexpanded particles, or combinations thereof. The thermally expanded particles refer to particles that have been pre-expanded by heat and has little or no change in size due to heat or pressure applied during the process of forming the polishing layer. The unexpanded particles are particles that have not been pre-expanded, and refer to particles whose final size is determined by expansion by heat or pressure applied during the process of forming the polishing layer.

The expandable particle may include an outer shell made of a resin and a swelling-inducing component present inside the outer shell.

For example, the outer shell may include a thermoplastic resin, and the thermoplastic resin may include one or more selected from the group consisting of a vinylidene chloride-based copolymer, an acrylonitrile-based copolymer, a methacrylonitrile-based copolymer, and an acrylic copolymer.

The swelling-inducing component may include one selected from the group consisting of a hydrocarbon compound, a chloro-fluoro compound, a tetraalkylsilane compound, and a combination thereof.

Specifically, the hydrocarbon compound may include one selected from the group consisting of ethane, ethylene, propane, propene, n-butane, isobutene, n-butene, isobutene, n-pentane, isopentane, neopentane, n-hexane, heptane, petroleum ether, and combinations thereof.

The chloro-fluoro compound may include one selected from the group consisting of trichlorofluoromethane (CCl₃F), dichlorodifluoromethane (CCl₂F₂), chlorotrifluoromethane (CClF₃), tetrafluoroethylene (CClF₂—CClF₂), and combinations thereof.

The tetraalkylsilane compound may include one selected from the group consisting of tetramethylsilane, trimethylethylsilane, trimethylisopropylsilane, trimethyl-n-propylsilane, and combinations thereof.

The solid foaming agent may optionally include inorganic treated particles. For example, the solid foaming agent may include expandable particles treated with an inorganic substance. In one embodiment, the solid foaming agent may include expandable particles treated with silica (SiO₂) particles. Treating the solid foaming agent with an inorganic substance may prevent agglomeration between multiple particles. When compared to a solid foaming agent that has not been treated with an inorganic substance, the surface of the solid foaming agent treated with the inorganic substance may have different chemical, electrical, and/or physical properties.

Based on 100 parts by weight of the urethane-based prepolymer, the content of the solid foaming agent may be approximately 0.5 parts by weight to approximately 10 parts by weight, for example, approximately 1 part by weight to approximately 3 parts by weight, for example, approximately 1.3 parts by weight to approximately 2.7 parts by weight, for example, approximately 1.3 parts by weight to approximately 2.6 parts by weight.

The type and content of the solid foaming agent may be determined according to the desired pore structure and physical properties of the polishing layer.

The vapor foaming agent may include an inert gas. The vapor foaming agent may be used as a pore-forming element by being added during the reaction between the second urethane-based prepolymer and the hardener.

When a gas does not participate in the reaction between the second urethane-based prepolymer and the hardener, the gas may be used as the inert gas without particular limitation. For example, the inert gas may include one selected from the group consisting of nitrogen gas (N₂), argon gas (Ar), helium gas (He), and combinations thereof. Specifically, the inert gas may include nitrogen gas (N₂) or argon gas (Ar).

The type and content of the vapor foaming agent may be determined depending on the desired pore structure and physical properties of the polishing layer.

In one embodiment, the foaming agent may include a solid foaming agent. For example, the foaming agent may consist of only a solid foaming agent.

The solid foaming agent may include expandable particles, and the expandable particles may include thermally expanded particles. For example, the solid foaming agent may only consist of thermally expanded particles. When the solid foaming agent does not include the unexpanded particles and consists only of thermally expanded particles, the variability of the pore structure decreases, but predictability in advance increases, which may be advantageous for realizing homogeneous pore characteristics throughout the entire region of the polishing layer.

In one embodiment, the average particle diameter of the thermally expanded particles may be approximately 5 μm to approximately 200 μm. The average particle diameter of the thermally expanded particles may be approximately 5 μm to approximately 100 μm, for example, approximately 10 μm to approximately 80 μm, for example, approximately 20 μm to approximately 70 μm, for example, approximately 20 μm to approximately 50 μm, for example, approximately 30 μm to approximately 70 μm, for example, approximately 25 μm to 45 μm, for example, approximately 40 μm to approximately 70 μm, for example, approximately 40 μm to approximately 60 μm. The average particle diameter is defined as D50 of the thermally expanded particles.

In one embodiment, the density of the thermally expanded particles may be approximately 30 kg/m² to approximately 80 kg/m², for example, approximately 35 kg/m² to approximately 80 kg/m², for example, approximately 35 kg/m² to approximately 75 kg/m², for example, approximately 38 kg/m² to approximately 72 kg/m², for example, approximately 40 kg/m² to approximately 75 kg/m², for example, approximately 40 kg/m² to approximately 72 kg/m².

In one embodiment, the foaming agent may include a vapor foaming agent. For example, the foaming agent may include a solid foaming agent and a vapor foaming agent. Details regarding the solid foaming agent are as described above.

The vapor foaming agent may be injected through a predetermined injection line during the process of mixing the second urethane-based prepolymer, the solid foaming agent, and the hardener. The injection rate of the vapor foaming agent may be approximately 0.8 L/min to approximately 2.0 L/min, for example, approximately 0.8 L/min to approximately 1.8 L/min, for example, approximately 0.8 L/min to approximately 1.7 L/min, for example, approximately 1.0 L/min to approximately 2.0 L/min, for example, approximately 1.0 L/min to approximately 1.8 L/min, for example, approximately 1.0 L/min to approximately 1.7 L/min.

The polishing layer composition may include optionally additives when necessary. The additive may include one selected from the group consisting of surfactants, pH adjusters, binders, antioxidants, heat stabilizers, dispersion stabilizers, and combinations thereof. Names such as ‘surfactant’ and ‘antioxidant’ above are arbitrary names based on the main role of the substance, and each substance does not necessarily perform only the functions limited to the role under the name.

When a material plays a role in preventing aggregation or overlap of pores, the material may be used as the surfactant without particular limitation. For example, the surfactant may include a silicon-based surfactant.

Based on 100 parts by weight of the second urethane-based prepolymer, the content of the surfactant may be approximately 0.2 parts by weight to approximately 2 parts by weight. Specifically, based on 100 parts by weight of the second urethane-based prepolymer, the content of the surfactant may be approximately 0.2 parts by weight to approximately 1.9 parts by weight, for example, approximately 0.2 parts by weight to approximately 1.8 parts by weight, for example, approximately 0.2 parts by weight to approximately 1.7 parts by weight, for example, approximately 0.2 parts by weight to approximately 1.6 parts by weight, for example, approximately 0.2 parts by weight to approximately 1.5 parts by weight, for example, approximately 0.5 parts by weight to 1.5 parts by weight. Within this range, pores derived from the vapor foaming agent may be stably formed and maintained within a mold.

The reaction rate regulator plays the role of promoting or delaying a reaction, and depending on the purpose, a reaction accelerator, a reaction retardant, or both may be used. The reaction rate regulator may include a reaction accelerator. For example, the reaction accelerator may include one or more reaction accelerators selected from the group consisting of tertiary amine compounds and organometallic compounds.

Specifically, the reaction rate regulator may include one or more selected from the group consisting of triethylenediamine, dimethylethanolamine, tetramethylbutanediamine, 2-methyl-triethylenediamine, dimethylcyclohexylamine, triethylamine, triisopropanolamine, 1,4-diazabicyclo(2,2,2)octane, bis(2-methylaminoethyl) ether, trimethylaminoethylethanolamine, N,N,N,N,N″-pentamethyldiethylenetriamine, dimethylaminoethylamine, dimethylaminopropylamine, benzyldimethylamine, N-ethylmorpholine, N,N-dimethylaminoethylmorpholine, N,N-dimethylcyclohexylamine, 2-methyl-2-azanorbornane, dibutyltin dilaurate, stannous octoate, dibutyltin diacetate, dioctyltin diacetate, dibutyltin maleate, dibutyltin di-2-ethylhexanoate, and dibutyltin dimercaptide. Specifically, the reaction rate regulator may include one or more selected from the group consisting of benzyldimethylamine, N,N-dimethylcyclohexylamine, and triethylamine.

Based on 100 parts by weight of the second urethane-based prepolymer, the content of the reaction rate regulator may be approximately 0.05 parts by weight to approximately 2 parts by weight, for example, approximately 0.05 parts by weight to approximately 1.8 parts by weight, for example, approximately 0.05 parts by weight to approximately 1.7 parts by weight, for example, approximately 0.05 parts by weight to approximately 1.6 parts by weight, for example, approximately 0.1 parts by weight to approximately 1.5 parts by weight, for example, approximately 0.1 parts by weight to approximately 0.3 parts by weight, for example, approximately 0.2 parts by weight to approximately 1.8 parts by weight, for example, approximately 0.2 parts by weight to approximately 1.7 parts by weight, for example, approximately 0.2 parts by weight to approximately 1.6 parts by weight, for example, approximately 0.2 parts by weight to approximately 1.5 parts by weight, for example, approximately 0.5 parts by weight to approximately 1 part by weight. When the content of the reaction rate regulator satisfies the above-mentioned content range, by appropriately controlling the curing reaction rate of the preliminary composition, a polishing layer with pores of a desired size and hardness may be formed.

In one embodiment, the density of the polishing layer 10 may be approximately 0.50 g/cm³ to approximately 1.20 g/cm³, for example, approximately 0.50 g/cm³ to approximately 1.10 g/cm³, for example, approximately 0.50 g/cm³ to approximately 1.00 g/cm³, for example, approximately 0.60 g/cm³ to approximately 0.90 g/cm³, for example, approximately 0.70 g/cm³ to approximately 0.90 g/cm³. The polishing layer 10, whose density satisfies the range, may provide a polishing surface with appropriate mechanical properties to a polishing object through the polishing surface thereof. As a result, the polishing flatness of a polishing target surface may be excellent, and the occurrence of defects such as scratches may be effectively prevented. In addition, when the physical properties of the polishing layer 10 show excellent compatibility with the mechanical and physical properties of the window 102, polishing may proceed smoothly throughout the polishing surface and the entire top cross-section of the window 102, and thus the degree of wear of the window 102 may be minimized. In addition, even when wear of the window 102 progresses, the wear area in the entire light transmission region does not exceed the appropriate range, so the polishing endpoint detection function through the window 102 may be maintained excellently for a long time.

In one embodiment, the tensile strength of the polishing layer 10 may be approximately 15 N/mm² to approximately 30 N/mm², for example, approximately 15 N/mm² to approximately 28 N/mm², for example, approximately 15 N/mm² to approximately 27 N/mm², for example, approximately 17 N/mm² to approximately 27 N/mm², for example, approximately 20 N/mm² to approximately 27 N/mm². When the tensile strength was measured, a polishing layer was processed to a thickness of 2 mm, and the polishing layer was cut into a size of 4 cm×1 cm (horizontal×vertical) to prepare a sample. For the sample, the highest strength value just before fracture was measured using a universal testing machine (UTM) at a speed of 50 mm/min. Based on the result, the tensile strength was determined. The polishing layer 10, which has a tensile strength satisfying the above range, may provide a polishing surface with appropriate mechanical properties to a polishing object through the polishing surface thereof. As a result, the polishing flatness of a polishing target surface may be excellent, and the occurrence of defects such as scratches may be effectively prevented. In addition, when the physical properties of the polishing layer 10 show excellent compatibility with the mechanical and physical properties of the window 102, polishing may proceed smoothly throughout the polishing surface and the entire top cross-section of the window 102, and thus the degree of wear of the window 102 may be minimized. In addition, even when wear of the window 102 progresses, the wear area in the entire light transmission region does not exceed the appropriate range, so the polishing endpoint detection function through the window 102 may be maintained excellently for a long time.

In one embodiment, the elongation of the polishing layer 10 may be approximately 100% or more, for example, approximately 100% to approximately 200%, for example, approximately 110% to approximately 160%. When the elongation was measured, a polishing layer was processed to a thickness of 2 mm, and the polishing layer was cut into a size of 4 cm×1 cm (horizontal×vertical) to prepare a sample. For the sample, the maximum deformation length just before fracture was measured using a universal testing machine (UTM) at a speed of 50 mm/min. The elongation was expressed as a percentage (%) of the ratio of the maximum deformed length to the initial length. When the elongation of the polishing layer 10 satisfies the range, the polishing layer 10 may provide a polishing surface with appropriate mechanical properties to a polishing object through the polishing surface thereof. As a result, the polishing flatness of a polishing target surface may be excellent, and the occurrence of defects such as scratches may be effectively prevented. In addition, when the physical properties of the polishing layer 10 show excellent compatibility with the mechanical and physical properties of the window 102, polishing may proceed smoothly throughout the polishing surface and the entire top cross-section of the window 102, and thus the degree of wear of the window 102 may be minimized. In addition, even when wear of the window 102 progresses, the wear area in the entire light transmission region does not exceed the appropriate range, so the polishing endpoint detection function through the window 102 may be maintained excellently for a long time.

As described above, the support layer 20 may provide an improved leak prevention function to the polishing pad 100 by including the compressed region (CR). In addition, the support layer 20 may serve as a buffer for relieving external pressure or external shock that may be transmitted to the polishing target surface during the polishing process through the non-compressed region (NCR).

The support layer 20 may include non-woven fabric or suede, without being limited thereto. In one embodiment, the support layer 20 may include non-woven fabric. The ‘non-woven fabric’ refers to a three-dimensional network of non-woven fiber. Specifically, the support layer 20 may include non-woven fabric and a resin impregnated into the non-woven fabric.

For example, the non-woven fabric may be a nonwoven fabric of fiber including one selected from the group consisting of polyester fiber, polyamide fiber, polypropylene fiber, polyethylene fiber, and combinations thereof.

For example, the resin impregnated into the non-woven fabric may include one selected from the group consisting of a polyurethane resin, a polybutadiene resin, a styrene-butadiene copolymer resin, a styrene-butadiene-styrene copolymer resin, an acrylonitrile-butadiene copolymer resin, a styrene-ethylene-butadiene-styrene copolymer resin, a silicon rubber resin, a polyester-based elastomer resin, a polyamide-based elastomer resin, and combinations thereof.

In one embodiment, the support layer 20 may include a non-woven fabric of fiber including polyester fiber impregnated with a resin including a polyurethane resin. In this case, in a region near where the window 102 is placed, the performance of the support layer 20 that supports the window 102 may be excellent. Accordingly, polishing progresses smoothly across the polishing surface and the entire top cross-section of the window 102, minimizing the degree of wear of the window 102. In addition, even when wear of the window 102 progresses, the wear area in the entire light transmission region does not exceed the appropriate range, so the polishing endpoint detection function through the window 102 may be maintained excellently for a long time.

For example, the thickness of the support layer 20 may be approximately 0.5 mm to approximately 2.5 mm, for example, approximately 0.8 mm to approximately 2.5 mm, for example, approximately 1.0 mm to approximately 2.5 mm, for example, approximately 1.0 mm to approximately 2.0 mm, for example, approximately 1.2 mm to approximately 1.8 mm. Referring to FIG. 2, the thickness of the support layer 20 may be the thickness (d2) of the non-compressed region (NCR).

The Asker C hardness of the surface of the support layer 20, for example, the third surface 21, may be approximately 60 to approximately 80, for example, approximately 65 to approximately 80. When the surface hardness on the third surface 21 satisfies the range with Asker C hardness, sufficient support rigidity to support the polishing layer 10 may be secured, and excellent interfacial adhesion with the second surface 12 may be achieved through the second adhesive layer 40.

The density of the support layer 20 may be approximately 0.10 g/cm³ to approximately 1.00 g/cm³, for example, approximately 0.10 g/cm³ to approximately 0.80 g/cm³, for example, approximately 0.10 g/cm³ to approximately 0.70 g/cm³, for example, approximately 0.10 g/cm³ to approximately 0.60 g/cm³, for example, approximately 0.10 g/cm³ to approximately 0.50 g/cm³, for example, approximately 0.20 g/cm³ to approximately 0.40 g/cm³. The support layer 20, which has a density that satisfies the range, may exhibit an excellent cushioning effect based on the high elasticity of the non-compressed region (NCR). The compressed region (CR) is compressed at a predetermined compression ratio compared to the non-compressed region (NCR), which may be more advantageous for forming a high-density region.

The compressibility of the support layer 20 may be approximately 1% to approximately 20%, for example, approximately 3% to approximately 15%, for example, approximately 5% to approximately 15%, for example, approximately 6% to approximately 14%. When the compressibility was measured, the support layer was cut to a size of 5 cm×5 cm (horizontal×vertical) (thickness: 2 mm). Then, the thickness of a cushion layer was measured when a stress load of 85 g was maintained for 30 seconds from a no-load state, and the measured thickness was referred to as T1 (mm). Then, the thickness of the support layer was measured when an additional stress load of 800 g was applied from the T1 state and maintained for 3 minutes, and the measured thickness was referred to as T2 (mm). Then, compressibility was calculated according to the formula (T1−T2)/T1×100. When the compressibility of the support layer 20 satisfies the range, the compressed region (CR) may be more advantageous in forming a high-density region that is effective in preventing water leakage. In addition, the performance of the support layer 20, which supports the polishing layer 10, may be excellent, and thus polishing progresses smoothly across the polishing surface and the entire top cross-section of the window 102, minimizing the degree of wear of the window 102. In addition, even when wear of the window 102 progresses, the wear area in the entire light transmission region does not exceed the appropriate range, so the polishing endpoint detection function through the window 102 may be maintained excellently for a long time.

The compressive modulus of the support layer 20 may be approximately 60% to approximately 95%, for example, approximately 70% to approximately 95%, for example, approximately 70% to approximately 92%. When the compressive modulus was measured, the support layer was cut into a size of 5 cm×5 cm (horizontal×vertical) (thickness: 2 mm). Then, the thickness of a cushion layer was measured when a stress load of 85 g was maintained for 30 seconds from a no-load state, and the measured thickness was referred to as T1 (mm). Then, the thickness of the support layer was measured when a stress load of 800 g was additionally applied from the T1 state and maintained for 3 minutes, and the measured thickness was referred to as T2 (mm). Then, the thickness of the support layer was measured when a stress load of 800 g was removed from the T2 state and restored while maintaining the stress load of 85 g for 1 minute, and the measured thickness was referred to as T3. The compressive modulus was calculated according to the formula (T3−T2)/(T1−T2)×100. When the compressive modulus of the support layer 20 satisfies the range, the compressed region (CR) may be more advantageous in forming a high-density region that is effective in preventing water leakage. In addition, the performance of the support layer 20, which supports the polishing layer 10, may be excellent, and thus polishing progresses smoothly across the polishing surface and the entire top cross-section of the window 102, minimizing the degree of wear of the window 102. In addition, even when wear of the window 102 progresses, the wear area in the entire light transmission region does not exceed the appropriate range, so the polishing endpoint detection function through the window 102 may be maintained excellently for a long time.

When the value of Equation 1 of the polishing pad 100 satisfies a predetermined range, the window 102, as a heterogeneous part, may be prevented from having a negative impact on polishing performance. In addition, the polishing endpoint detection function of the window 102 may be maintained excellently for a long time. That is, the entire light transmission region of the window 102 may not show any wear during the polishing process. Even when the entire light transmission region is worn, the combined result of the degree of wear and the area ratio of the worn region in the entire light transmission region may have an effect suitable for maintaining the polishing endpoint detection function for a long time.

Another embodiment of the present invention provides a method of fabricating a semiconductor device, the method including a step of providing a polishing pad having a polishing layer including a first surface that is a polishing surface and a second surface that is the back surface of the first surface, first through holes formed to penetrate from the first surface to the second surface, and windows placed within the first through holes; and a step of positioning a polishing object so that a polishing target surface of the polishing object is in contact with the first surface and then polishing the polishing object by rotating the polishing pad and the polishing object relative to each other under pressure conditions, wherein the polishing object includes a semiconductor substrate, the polishing pad further includes a support layer placed on a side of the second surface of the polishing layer, and the support layer includes a third surface that is placed on a side of the polishing layer and a fourth surface that is the back surface of the third surface, and includes second through holes formed to penetrate from the third surface to the fourth surface and connected to the first through holes, wherein the windows include a first region where a height of a top surface is lower than a height of the first surface, and the polishing pad has a value of 0.00 to 1.45 as calculated by Equation 1:

$$\frac{P}{T} \times ( Fa - Ia ) \qquad [ Equation 1 ]$$

### [Condition 1]

In a state in which the first surface and the polishing target surface of the polishing object are arranged to face each other, polishing is performed under Condition 1 that a rotation speed of the polishing object is 87 rpm, a rotation speed of the polishing pad is 93 rpm, a pressing load of the polishing target surface of the polishing object against the first surface is 3.5 psi, a flow rate of distilled water injected onto the first surface is 200 mL/min, a rotation speed of a conditioner that processes the first surface is 101 rpm, and a vibration movement speed of the conditioner is 19 times/min.

In Equation 1, T is an area (mm²) value of a light transmission region of the window top surface, P is an area (mm²) value of a worn region of the light transmission region after polishing for 20 hours under Condition 1, Ia is a surface roughness (Sa, μm) value of the first region before polishing, and Fa is a surface roughness (Sa, μm) value of the first region after polishing for 20 hours under Condition 1.

In Equation 1, T and P are each numerical values of the unit mm² and consist only of unitless numbers. Ia and Fa are each numerical values of the unit μm and consist only of unitless numbers.

Condition 1 is a measurement condition for deriving P and Fa, and does not limit the process conditions of the method of fabricating a semiconductor device.

In the method of fabricating a semiconductor device, in cases where all details regarding the polishing pad are not repeatedly described below, as well as cases where all details regarding the polishing pad are repeatedly described below, all matters described for explanation of the above-described implementations and technical advantages thereof can be equally applied hereinafter. By applying the polishing pad with the above-mentioned characteristics to the semiconductor device fabrication method, the semiconductor device fabricated using the method may secure high quality based on the excellent polishing results of the semiconductor substrate.

In one embodiment, the value of Equation 1 may be approximately 0.00 to approximately 1.45, for example, approximately 0.00 to approximately 1.40, for example, approximately 0.00 to approximately 1.35, for example, approximately 0.00 to approximately 1.30, for example, approximately 0.00 to approximately 1.25, for example, approximately 0.00 to approximately 1.20, for example, approximately 0.00 to approximately 1.15, for example, approximately 0.00 to approximately 1.10, for example, approximately 0.00 to approximately 1.05, for example, approximately 0.00 to approximately 1.00, for example, approximately 0.00 to approximately 0.95, for example, approximately 0.00 to approximately 0.90, for example, approximately 0.00 to approximately 0.85, for example, approximately 0.00 to approximately 0.80, for example, approximately 0.00 or more and less than approximately 0.80. When the value of Equation 1 satisfies the above range, the windows show that an entire light transmission region is not worn at all during a polishing process, or even when the region is worn, the combination of the degree of wear and the area of the worn region in the entire light transmission region may show an appropriate effect for maintaining the polishing endpoint detection function for a long time.

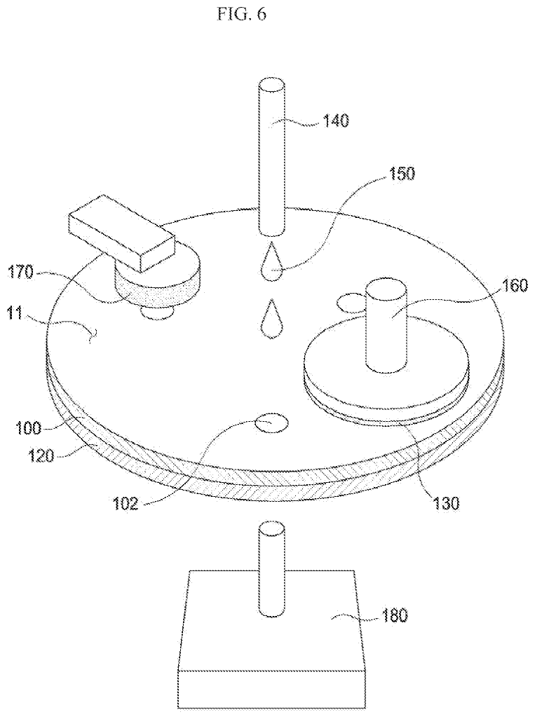

FIG. 6 is a schematic diagram schematically showing the device configuration of the method of fabricating a semiconductor device according to one embodiment. Referring to FIG. 6, the polishing pad 100 may be provided on a surface plate 120. Specifically, the polishing pad 100 may be provided on the surface plate 120 so that the side of the second surface 12 of the polishing layer 10 faces the surface plate 120. The polishing pad 100 may be placed on the surface plate 120 so that the top cross-section of the window 102 and the first surface 11 are exposed as the outermost surface.

The method of fabricating a semiconductor device may include a step of polishing a polishing object, and the polishing object 130 may include a semiconductor substrate. The polishing object 130 may be placed so that the polishing target surface thereof contacts the first surface 11 and the top cross-section of the window 102. The polishing target surface of the polishing object 130 may directly contact the first surface 11 and the top cross-section of the window 102, or may indirectly contact the first surface 11 and the top cross-section of the window 102 through fluid slurry. Here, the fact that the polishing target surface of the polishing object 130 is placed in contact with the first surface 11 includes both cases of direct or indirect contact.

In one embodiment, the polishing object 130 may be mounted on a polishing head 160 so that the polishing target surface of the polishing object 130 faces the polishing pad 100. By driving the polishing head 160, the polishing target surface of the polishing object 130 may be polished under pressurizing conditions for the first surface 11. For example, the load with which the polishing target surface of the polishing object 130 is pressed against the first surface 11 may be selected depending on the purpose in the range of approximately 0.01 psi to approximately 20 psi, for example, approximately 0.1 psi to approximately 15 psi, without being limited thereto.

The polishing target surface of the polishing object 130 may be placed in contact with the first surface 11 and then polished while rotating relative to each other. The polishing object 130 may be rotated by the rotational drive of the polishing head 160, and the polishing pad 100 provided with the first surface 11 may be rotated by the rotational drive of the surface plate 120. The rotation direction of the polishing object 130 and the rotation direction of the polishing pad 100 may be the same or opposite. In this specification, ‘relative rotation’ is interpreted to include both rotation in the same direction or rotation in opposite directions. The rotation speed of the polishing pad 100 may be selected depending on the purpose in the range of approximately 10 rpm to approximately 500 rpm, and may be, for example, approximately 30 rpm to approximately 200 rpm, without being limited thereto. The rotation speed of the polishing object 130 may be approximately 10 rpm to approximately 500 rpm, for example, approximately 30 rpm to approximately 200 rpm, for example, approximately 50 rpm to approximately 150 rpm, for example, approximately 50 rpm to approximately 100 rpm, for example, approximately 50 rpm to approximately 90 rpm, without being limited thereto. The rotation speed of the polishing object 130 and the rotation speed of the polishing pad 100 may be the same or different. When the rotation speeds of the polishing object 130 and the polishing pad 100 satisfy the range, the fluidity of slurry due to centrifugal force facilitates polishing that progresses across the interface between the top cross-section of the window 102 and the first surface 11. Thus, the entire light transmission region of the window 102 may not show any wear during the polishing process. Even when the entire light transmission region is worn, the combined result of the degree of wear and the area ratio of the worn region in the entire light transmission region may have an effect suitable for maintaining the polishing endpoint detection function for a long time.

In one embodiment, the method of fabricating a semiconductor device may further include a step of supplying polishing slurry 150 onto the first surface 11. The polishing slurry 150 may be sprayed onto the first surface 11 through a supply nozzle 140, and the flow rate of the polishing slurry 150 sprayed through the supply nozzle 140 may be approximately 10 ml/min to approximately 1,000 ml/min, for example, approximately 10 ml/min to approximately 800 ml/min, for example, approximately 50 ml/min to approximately 500 ml/min, without being limited thereto. When the flow rate of the polishing slurry 150 satisfies the range, the polishing slurry 150 may move smoothly across the window 102 and the first surface 11. Accordingly, the entire light transmission region of the window 102 may not show any wear during the polishing process. Even when the entire light transmission region is worn, the combined result of the degree of wear and the area ratio of the worn region in the entire light transmission region may have an effect suitable for maintaining the polishing endpoint detection function for a long time.

The polishing slurry 150 may include polishing particles. For example, the polishing particles may include silica particles or ceria particles, without being limited thereto.

In one embodiment, the method of fabricating a semiconductor device may further include a step of roughening the first surface 11 using a conditioner 170. For example, the step of roughening the first surface 11 using the conditioner 170 may be performed simultaneously with the step of polishing the polishing object 130. By roughening the first surface 11 through the conditioner 170, the first surface 11 may maintain a surface condition suitable for polishing.

In one embodiment, the conditioner 170 may rotate and roughen the first surface 11. The rotation speed of the conditioner 170 may be, for example, approximately 50 rpm to approximately 150 rpm, for example, approximately 50 rpm to approximately 120 rpm, for example, approximately 90 rpm to approximately 120 rpm.

In one embodiment, the conditioner 170 may roughen the first surface 11 while being pressed against the first surface 11. For example, the pressing load of the conditioner 170 against the first surface 11 may be approximately 1 lb to approximately 10 lb, for example, approximately 3 lb to approximately 9 lb.

In one embodiment, the conditioner 170 may roughen the first surface 11 while vibrating in a path that travels from the center of the polishing pad 100 to the end of the polishing pad 100. When the reciprocating movement of the conditioner 170 between the center of the polishing pad 100 and the end of the polishing pad 100 is calculated as one time, the vibration movement speed of the conditioner 170 may be, for example, approximately 10 times/minute to approximately 30 times/minute, for example, approximately 10 times/minute to approximately 25 times/minute, for example, approximately 15 times/minute to approximately 25 times/minute.

Since the first surface 11, which is the polishing surface, is polished under the condition that the semiconductor substrate 130 is pressed against the polishing surface while polishing is in progress, as the pore structure exposed to the surface is pressed, surface roughness is reduced, gradually changing to a state unsuitable for polishing. To prevent this problem, the first surface 11 may be cut through the conditioner 170, which has a surface capable of being roughened, while maintaining the surface in a state suitable for polishing. At this time, when the cut parts of the first surface 11 are not discharged quickly and remain as debris on the polishing surface, defects such as scratches may occur on the polishing target surface of the semiconductor substrate 130. When the driving conditions, that is, rotation speed and pressurization conditions of the conditioner 170 satisfy the range, the surface structure of the first surface 11 may be maintained in a state suitable for polishing, and the cut parts of the first surface 11 may be discharged without remaining in the first region 1102. In addition, the surface condition of the first surface 11 may maintain appropriate compatibility with the top cross-section of the window 102. Thus, the entire light transmission region of the window 102 may not show any wear during the polishing process. Even when the entire light transmission region is worn, the combined result of the degree of wear and the area ratio of the worn region in the entire light transmission region may be more advantageous to maintain the polishing endpoint detection function for a long time.

The method of fabricating a semiconductor device may further include a step of detecting the polishing endpoint of the polishing target surface of the semiconductor substrate 130 by allowing light emitted from a light source 180 to travel through the window 102. Referring to FIGS. 1 and 6, By connecting the second through hole 201 with the first through hole 101, an optical path through which light emitted from the light source 180 penetrates the entire thickness from the top cross-section of the polishing pad 100 to the bottom cross-section thereof may be secured, and an optical endpoint detection method through the window 102 may be applied.

In one embodiment, the wavelength of light emitted from the light source 180 may be approximately 350 nm to approximately 800 nm. By using light in the above wavelength range to detect a polishing endpoint, the technical advantage of the polishing pad 100 satisfying Equation 1 within a predetermined range may be maximized.

According to the method of fabricating a semiconductor device, by applying the polishing pad whose value of Equation 1 satisfies a predetermined range as a process part, to ensure the polishing endpoint detection function, the window provided within the polishing pad may be prevented from having a negative impact on polishing performance as a foreign accessory to the polishing layer. In addition, the entire light transmission region of the window 102 may not show any wear during the polishing process. Even when the entire light transmission region is worn, the combined result of the degree of wear and the area ratio of the worn region in the entire light transmission region may be more advantageous to maintain the polishing endpoint detection function for a long time.

Hereinafter, specific examples of the present invention are described. However, the examples described below is only intended to specifically illustrate or explain the present invention, and as a result, the scope of rights of the present invention is not interpreted to be limited, and the scope of rights of the present invention is determined by the scope of the claims.

### PREPARATION EXAMPLES

### Preparation Example 1: Preparation of Polishing Layer Composition

Based on 100 parts by weight in total of a diisocyanate component, 72 parts by weight of 2,4-TDI, 18 parts by weight of 2,6-TDI, and 10 parts by weight of H₁₂MDI were mixed. Based on 100 parts by weight in total of a polyol component, 90 parts by weight of PTMG and 10 parts by weight of DEG were mixed. Based on 100 parts by weight in total of the diisocyanate component, 148 parts by weight of the polyol component was mixed to prepare a mixed raw material. The mixed raw material was injected into a four-necked flask and the reaction was performed at 80° C. to prepare a polishing layer composition including a urethane-based prepolymer and having an isocyanate group content (NCO %) of 9.3% by weight.

### Preparation Example 2: Preparation of Window Composition

Based on 100 parts by weight in total of a diisocyanate component, 64 parts by weight of 2,4-TDI, 16 parts by weight of 2,6-TDI, and 20 parts by weight of H₁₂MDI were mixed. Based on 100 parts by weight in total of a polyol component, 47 parts by weight of PTMG, 47 parts by weight of PPG, and 6 parts by weight of DEG were mixed. Based on 100 parts by weight in total of the diisocyanate component, 180 parts by weight of the polyol component was mixed to prepare a mixed raw material. The mixed raw material was injected into a four-necked flask and the reaction was performed at 80° C. to prepare a window composition including a urethane-based prepolymer and having an isocyanate group content (NCO %) of 8% by weight.

### EXAMPLES AND COMPARATIVE EXAMPLES

### Example 1

Based on 100 parts by weight of the polishing layer composition of Preparation Example 1, 1.0 part by weight of a solid foaming agent (Nouryon Co.) and 4,4′-methylenebis (2-chloroaniline) (MOCA) as a hardener were mixed so that the molar ratio of the amine group (—NH₂) of the MOCA to the isocyanate group (—NCO) of 1.0 in the polishing layer composition is 0.95. The polishing layer composition was injected into a mold having dimensions of 1,000×mm×1,000 mm×3 mm in width, length, and height and preheated at 90° C. at a discharge rate of 10 kg/min. At the same time, nitrogen (N₂) gas as a vapor foaming agent was injected thereto at an injection rate of 1.0 L/min. Then, the polishing layer was formed by post-curing the preliminary composition under a temperature condition of 110° C. The polishing layer was processed to a thickness of 2.03 mm through lathe turning, and a concentric circular groove with a width of 460 μm, a depth of 0.85 mm, and a pitch of 3.0 mm was formed on the polishing surface.

Based on 100 parts by weight of the window composition of Preparation Example 2, 4,4′-methylenebis(2-chloroaniline) (MOCA) as a hardener was mixed so that the molar ratio of the amine group (—NH₂) of the MOCA to the isocyanate group (—NCO) of 1.0 in the polishing layer composition is 0.95. The window composition was injected into a mold having dimensions of 1,000×mm×1,000 mm×3 mm in width, length, and height and preheated at 90° C. at a discharge rate of 10 kg/min, and post-curing was performed at a temperature of 110° C. to form a window. The window had a circular structure with a thickness of 2 mm and a diameter of 19.5 mm.

On the top surface of the window, the first region was formed by processing a concave portion having a depth (h1) from the top surface as shown in Table 1 below and a width (w3) as shown in Table 1 below.

A support layer with a thickness of 1.4 mm was prepared by impregnating a non-woven fabric containing a polyester resin fiber with a urethane-based resin.

A first through hole was formed to penetrate from the first surface, which is the polishing surface of the polishing layer, to the second surface, which is the back surface thereof. At this time, the first through hole was formed in a cylindrical shape having a diameter of 20 mm.

Next, after placing an adhesive film containing a thermoplastic urethane-based adhesive on one surface (third surface) of the support layer, the adhesive film was brought into contact with the second surface of the polishing layer and then heat-sealed at 140° C. using a pressure roller. Then, cutting was performed from the bottom cross-section of the support layer to form a second through hole that penetrate the support layer in the thickness direction. At this time, the second through hole was formed within a region corresponding to the first through hole and was interconnected with the first through hole, and the second through hole was formed in a cylindrical shape with a diameter of 12 mm.

The window was placed inside the first through hole. At this time, an adhesive with a diameter of 16 mm was applied onto the third surface inside the first through hole, the window was placed to be supported by the third surface, and the window was pressed so that the window is fixed to the first through hole. Through this process, a polishing pad was manufactured.

### Example 2

A polishing pad was manufactured in the same manner as Example 1, except that a first region was formed on the top surface of the window by processing a concave portion having a depth (h1) from the top surface as shown in Table 1 below and a width (w3) as shown in Table 1 below.

### Example 3

A polishing pad was manufactured in the same manner as Example 1, except that a first region was formed on the top surface of the window by processing a concave portion having a depth (h1) from the top surface as shown in Table 1 below and a width (w3) as shown in Table 1 below. The first region was processed to be located in the center of the window. That is, the first region was formed in a circle within 2.25 mm from the end of the window.

### Comparative Example 1

A polishing pad was manufactured in the same manner as Example 1, except that a first region was formed on the top surface of the window by processing a concave portion having a depth (h1) from the top surface as shown in Table 1 below and a width (w3) as shown in Table 1 below. The first region was processed to be located in the center of the window. That is, the first region was formed in a circle within 3.25 mm from the end of the window.

### Comparative Example 2

A polishing pad was manufactured in the same manner as Example 1, except that a first region was formed on the top surface of the window by processing a concave portion having a depth (h1) from the top surface as shown in Table 1 below and a width (w3) as shown in Table 1 below.

### <Evaluation>

### Experimental Example 1: Roughness Measurement

Each polishing pad manufactured in Examples and Comparative Examples was mounted on the surface plate of polishing equipment (CTS AP300), a silicon wafer (TEOS wafer) was mounted on a polishing head, and polishing was performed for 20 hours under the conditions that the rotation speed of the polishing head was 87 rpm, the pressing load of the polishing head against the polishing pad was 3.5 psi, the rotation speed of the surface plate was 93 rpm, distilled water (DI water) was injected at an injection flow rate of 200 mL/min, the rotation speed of a conditioner (CI 45) was 101 rpm, and the vibration movement speed of the conditioner was 19 times/min. Then, the surface roughness (Sa, Spk, Svk) of the window first region before and after the polishing was measured using a surface roughness meter (Burker Co., Contour GT). The results are shown in Table 1 below.

### Experimental Example 2: Measurement of Areas of Light Transmission Region and Worn Region

For each polishing pad manufactured in Examples and Comparative Examples, in the top surfaces of the window, the area of a region where light can be transmitted by the first through hole and the second through hole was derived using the diameter of the second through hole, and the derived area was set as the area value of the light transmission region. After polishing the polishing pad for 20 hours under the same conditions as in Experimental Example 1, the area of a worn region in the light transmission region was derived using an area calculation software (i-solution).

### Experimental Example 3: Measurement of Light Transmittance and Pad Lifespan

For each polishing pad manufactured in Examples and Comparative Examples, After polishing the polishing pad for 20 hours under the same conditions as in Experimental Example 1, for light with a wavelength of 450 nm, the light transmittance of each window was measured using a spectrophotometer (Shimadzu Co., UV-2450). For light with a wavelength of 450 nm, the polishing time until the light transmittance becomes 2.5% or less was considered the lifespan of the polishing pad.

TABLE 1

| | | | | | | | | | Comparative | | Comparative | |
|---|---|---|---|---|---|---|---|---|---|---|---|---|
| Classification | | Unit | Example 1 | | Example 2 | | Example 3 | | Example 1 | | Example 2 | |
| First | Depth (h1) | mm | 0.5 | | 1 | | 0.5 | | 0.3 | | 0 | |
| region | Diameter | mm | 19.5 | | 19.5 | | 15 | | 12 | | 19.5 | |
| structure | (w3) | | | | | | | | | | | |
| Through | Diameter of | mm | 20 | | 20 | | 20 | | 20 | | 20 | |
| hole | first through | | | | | | | | | | | |
| structure | hole (w4) | | | | | | | | | | | |
| | Diameter of | mm | 12 | | 12 | | 12 | | 12 | | 12 | |
| | second | | | | | | | | | | | |
| | through hole | | | | | | | | | | | |
| | (w5) | | | | | | | | | | | |
| Rough- | Measurement | — | After | Before | After | Before | After | Before | After | Before | After | Before |
| ness | point | | pol- | pol- | pol- | pol- | pol- | pol- | pol- | pol- | pol- | pol- |
| | | | ishing | ishing | ishing | ishing | ishing | ishing | ishing | ishing | ishing | ishing |
| | Sa | μm | 2.2 | 1.2 | 1.9 | 1.1 | 1.1 | 1.1 | 2.7 | 1.0 | 3.2 | 1.1 |
| | Spk | μm | 2.2 | 1.4 | 1.8 | 1.3 | 1.3 | 1.3 | 2.8 | 1.2 | 3.4 | 1.4 |
| | Svk | μm | 4.1 | 1.3 | 3.4 | 1.2 | 1.2 | 1.2 | 4.8 | 1.1 | 5.2 | 1.2 |

| Light transmittance | | % | 19% | 22% | 23% | 3% | 3% |
|---|---|---|---|---|---|---|---|
| (@450 nm) | | | | | | | |
| Pad lifespan | | Time | 50 | 50 | 50 | 18 | 0.5 |
| Area of light | | mm² | 113.04 | 113.04 | 113.04 | 113.04 | 113.04 |
| transmission region | | | | | | | |
| Area of worn region | | mm² | 79.00 | 105.50 | 0.00 | 98.30 | 113.04 |
| Equation 1 | | — | 0.70 | 0.75 | 0.00 | 1.48 | 2.10 |
| Surface | Equation 2 | % | 83.33 | 72.73 | 0.00 | 170.00 | 190.91 |
| rough- | Equation 3 | % | 57.14 | 38.46 | 0.00 | 133.33 | 142.86 |
| ness | Equation 4 | % | 215.38 | 183.33 | 0.00 | 336.36 | 333.33 |
| change | | | | | | | |
| Rate | | | | | | | |

Referring to Table 1, in the case of the polishing pads of Examples 1 to 3, the value of Equation 1 satisfied the range of approximately 0.00 or more and less than approximately 0.80, specifically, approximately 0.00 to approximately 0.78, more specifically, approximately 0.00 to approximately 0.75. Thus, compared to the polishing pads of Comparative Examples 1 and 2, in the case of the polishing pads of Examples 1 to 3, the entire window light transmission region of the polishing pad was not worn at all during the polishing process, or even when the entire window light transmission region was worn, the combined result of the degree of wear and the area ratio of the worn region in the entire light transmission region was advantageous in maintaining a polishing endpoint detection function for a long time.

Specifically, the value of Equation 1 of the polishing pad of Example 3 satisfies 0.00. Accordingly, when polishing is performed under predetermined conditions, the entire window light transmission region of the polishing pad is not worn at all, and thus the lifespan of the pad may be maximized. In the case of Examples 1 and 2, when polishing is performed under predetermined conditions, although there is some wear on the surface of the window, the degree of wear and the area ratio of a worn region in the entire light transmission region are appropriately controlled. Accordingly, the lifespan of the pad is realized similar to the case where there is no wear.

The value of Equation 1 of the polishing pads of Comparative Examples 1 and 2 exceeds approximately 1.45. Thus, the light transmittance of the window decreases rapidly. As a result, the polishing time, that is, the lifespan of the pad, until the transmittance of light with a wavelength of 450 nm becomes 2.5% or less is greatly reduced.

### DESCRIPTION OF SYMBOLS

100, 200, 300: POLISHING PAD
10: POLISHING LAYER
11: FIRST SURFACE
12: SECOND SURFACE
101: FIRST THROUGH HOLES
102: WINDOWS
1021: FIRST WINDOW
1022: SECOND WINDOW
1102: FIRST REGION
2102: SECOND REGION
20: SUPPORT LAYER
21: THIRD SURFACE
22: FOURTH SURFACE
201: SECOND THROUGH HOLES
30: FIRST ADHESIVE LAYER
40: SECOND ADHESIVE LAYER
111: GROOVE
112: PORES
113: FINE CONCAVE PORTION
120: SURFACE PLATE
130: POLISHING OBJECT
140: SUPPLY NOZZLE
150: POLISHING SLURRY
160: POLISHING HEAD
170: CONDITIONER
180: LIGHT SOURCE
h1: HEIGHT DIFFERENCE OF FIRST SURFACE-FIRST REGION
w3: DIAMETER OF FIRST REGION
CR: COMPRESSED REGION
NCR: NON-COMPRESSED REGION
d1: THICKNESS OF COMPRESSED REGION
d2: THICKNESS OF NON-COMPRESSED REGION
w1: WIDTH OF COMPRESSED REGION
d3: DEPTH OF GROOVE
w2: WIDTH OF GROOVE
p1: PITCH
d4: THICKNESS OF POLISHING LAYER
w4: DIAMETER OF FIRST THROUGH HOLE
w5: DIAMETER OF SECOND THROUGH HOLE
C: CENTER OF POLISHING PAD
C1: CENTER OF FIRST WINDOW
C2: CENTER OF SECOND WINDOW
L1: STRAIGHT LINE CONNECTING C-C1
L2: STRAIGHT LINE CONNECTING C-C2

1. A polishing pad, comprising:
a polishing layer comprising a first surface that is a polishing surface and a second surface that is a back surface of the first surface and comprising first through holes formed to penetrate from the first surface to the second surface;
windows placed within the first through holes; and
a support layer placed on a side of the second surface of the polishing layer, comprising a third surface that is placed on a side of the polishing layer and a fourth surface that is a back surface of the third surface, and comprising second through holes formed to penetrate from the third surface to the fourth surface and connected to the first through holes,
wherein the windows comprise a first region where a height of a top surface is lower than a height of the first surface, and the polishing pad has a value of 0.00 to 1.45 as calculated by Equation 1 below:
$$\frac{P}{T} \times ( Fa - Ia ) \qquad [ Equation 1 ]$$
[Condition 1]
In a state in which the first surface and a polishing target surface of a silicon wafer are arranged to face each other, polishing is performed under Condition 1 that a rotation speed of the silicon wafer is 87 rpm, a rotation speed of the polishing pad is 93 rpm, a pressing load of the polishing target surface of the silicon wafer against the first surface is 3.5 psi, a flow rate of distilled water injected onto the first surface is 200 mL/min, a rotation speed of a conditioner that processes the first surface is 101 rpm, and a vibration movement speed of the conditioner is 19 times/min.
In Equation 1,
T is an area value of a light transmission region of the window top surface,
P is an area (mm²) value of a worn region of the light transmission region after polishing for 20 hours under Condition 1,
Ia is a surface roughness (Sa, μm) value of the first region before polishing, and
Fa is a surface roughness (Sa, μm) value of the first region after polishing for 20 hours under Condition 1.

2. The polishing pad according to claim 1, comprising two or more first through holes, two or more second through holes, and two or more windows.

3. The polishing pad according to claim 1, wherein a height difference between the first surface and the first region is 100 μm to 1.5 m.

4. The polishing pad according to claim 1, wherein the windows further comprise a second region where a height of a top surface is equal to a height of the first surface,
the first region is located in a center of the window, and
the second region is located on the outer periphery of the window.

5. The polishing pad according to claim 1, wherein the windows have a light transmittance of 10% or more for light with a wavelength of 450 nm after polishing for 20 hours for a thickness of 2 mm under Condition 1.

6. The polishing pad according to claim 1, wherein, after polishing for a time under Condition 1, when the windows have a light transmittance of 2.5% or less for light with a wavelength of 450 nm, the α is 50 or more.

7. The polishing pad according to claim 1, wherein an Sa change rate of the first region calculated using Equation 2 below is 0% to 160%:
$$\frac{( Fa - Ia )}{Ia} \times 100 \qquad [ Equation 2 ]$$
In Equation 2, Ia is a surface roughness (Sa, μm) value of the first region before polishing, and Fa is a surface roughness (Sa, μm) value of the first region after polishing for 20 hours under Condition 1.

8. The polishing pad according to claim 1, wherein an Spk change rate of the first region calculated using Equation 3 below is 0% to 130%:
$$\frac{( Fp - Ip )}{Ip} \times 100 \qquad [ Equation 3 ]$$
In Equation 3, Ip is a surface roughness (Spk, μm) value of the first region before polishing, and Fp is a surface roughness (Spk, μm) value of the first region after polishing for 20 hours under Condition 1.

9. The polishing pad according to claim 1, wherein a surface roughness (Svk) change rate of the first region calculated using Equation 4 below is 0% to approximately 320%:
$$\frac{( Fv - Iv )}{Iv} \times 100 \qquad [ Equation 4 ]$$
In Equation 4, Iv is a surface roughness (Svk, μm) value of the first region before polishing, and Fv is a surface roughness (Svk, μm) value of the first region after polishing for 20 hours under Condition 1.

10. A method of fabricating a semiconductor device, comprising:
a step of providing a polishing pad having a polishing layer comprising a first surface that is a polishing surface and a second surface that is a back surface of the first surface, first through holes formed to penetrate from the first surface to the second surface, and windows placed within the first through holes; and
a step of positioning a polishing object so that a polishing target surface of the polishing object is in contact with the first surface and then polishing the polishing object by rotating the polishing pad and the polishing object relative to each other under pressure conditions,
wherein the polishing object comprises a semiconductor substrate,
the polishing pad further comprises a support layer placed on a side of the second surface of the polishing layer, and
the support layer comprises a third surface that is placed on a side of the polishing layer and a fourth surface that is a back surface of the third surface, and comprises second through holes formed to penetrate from the third surface to the fourth surface and connected to the first through holes,
wherein the windows comprise a first region where a height of a top surface is lower than a height of the first surface, and the polishing pad has a value of 0.00 to 1.45 as calculated by Equation 1:
$$\frac{P}{T} \times ( Fa - Ia ) \qquad [ Equation 1 ]$$
[Condition 1]
In a state in which the first surface and a polishing target surface of the polishing object are arranged to face each other, polishing is performed under Condition 1 that a rotation speed of the polishing object is 87 rpm, a rotation speed of the polishing pad is 93 rpm, a pressing load of the polishing target surface of the polishing object against the first surface is 3.5 ps, a flow rate of distilled water injected onto the first surface is 200 mL/min, a rotation speed of a conditioner that processes the first surface is 101 rpm, and a vibration movement speed of the conditioner is 19 times/min.
In Equation 1,
T is an area (mm²) value of a light transmission region of the window top surface,
P is an area (mm²) value of a worn region of the light transmission region after polishing for 20 hours under Condition 1,
la is a surface roughness (Sa, μm) value of the first region before polishing, and
Fa is a surface roughness (Sa, μm) value of the first region after polishing for 20 hours under Condition 1.

11. The method according to claim 10, further comprising a step of supplying polishing slurry to the first surface,
wherein the polishing slurry is sprayed onto the first surface through a supply nozzle, and a flow rate of the polishing slurry sprayed through the supply nozzle is 10 ml/min to 1,000 ml/min.

12. The method according to claim 10, wherein a rotation speed of each of the polishing object and the polishing pad is 10 rpm to 500 rpm.

13. The method according to claim 10, further comprising a step of roughening the first surface using a conditioner,
wherein a rotation speed of the conditioner is 50 rpm to 150 rpm, and a pressing load of the conditioner against the first surface is 1 lb to 10 lb.

14. The method according to claim 10, wherein a load with which the polishing target surface of the polishing object is pressed against the first surface is 0.01 psi to 20 psi.

15. The method according to claim 10, wherein a height difference between the first surface and the first region is 100 μm to 1.5 mm.

16. The method according to claim 10, wherein the windows further comprise a second region where a height of a top surface is equal to a height of the first surface,
the first region is located in a center of the window, and
the second region is located on the outer periphery of the window.

17. The method according to claim 10, wherein the windows have a light transmittance of 10% or more for light with a wavelength of 450 nm after polishing for 20 hours for a thickness of 2 mm under Condition 1.

18. The method according to claim 10, wherein, after polishing for α time under Condition 1, when the windows have a light transmittance of 2.5% or less for light with a wavelength of 450 nm, the α is 50 or more.

19. A polishing pad, comprising:
a polishing layer comprising a first surface that is a polishing surface and a second surface that is a back surface of the first surface and comprising first through holes formed to penetrate from the first surface to the second surface;
windows placed within the first through holes; and
a support layer placed on a side of the second surface of the polishing layer, comprising a third surface that is placed on a side of the polishing layer and a fourth surface that is a back surface of the third surface, and comprising second through holes formed to penetrate from the third surface to the fourth surface and connected to the first through holes,
wherein the windows comprise a first region where a height of a top surface is lower than a height of the first surface, and an Sa change rate of the first region calculated using Equation 2 below is 0% to 160%:
$$\frac{( Fa - Ia )}{Ia} \times 100 \qquad [ Equation 2 ]$$
[Condition 1]
In a state in which the first surface and a polishing target surface of a silicon wafer are arranged to face each other, polishing is performed under Condition 1 that a rotation speed of the silicon wafer is 87 rpm, a rotation speed of the polishing pad is 93 rpm, a pressing load of the polishing target surface of the silicon wafer against the first surface is 3.5 psi, a flow rate of distilled water injected onto the first surface is 200 mL/min, a rotation speed of a conditioner that processes the first surface is 101 rpm, and a vibration movement speed of the conditioner is 19 times/min.
In Equation 2,
Ia is a surface roughness (Sa, μm) value of the first region before polishing, and Fa is a surface roughness (Sa, μm) value of the first region after polishing for 20 hours under Condition 1.

20. The polishing pad according to claim 19, wherein an Spk change rate of the first region calculated using Equation 3 below is 0% to 130%:
$$\frac{( Fp - Ip )}{Ip} \times 100 \qquad [ Equation 3 ]$$
In Equation 3, Ip is a surface roughness (Spk, μm) value of the first region before polishing, and Fp is a surface roughness (Spk, μm) value of the first region after polishing for 20 hours under Condition 1.
